(19) United States
(12) Patent Application Publication
(10) Pub. No.: US 2023/0202300 A1
(43) Pub. Date: Jun. 29, 2023

(54) IMPROVED AUTOMOTIVE DISPLAY PANELS

(71) Applicant: Corning Incorporated, Corning, NY (US)

(72) Inventors: Amey Ganpat Badar, Hillsboro, OR (US); Kaikai Che, Corning, NY (US); Joseph Paul Gelhaus, New Canaan, CT (US); Paige Varner Kennedy, Philadelphia, PA (US); Evan Gray Kister, Painted Post, NY (US); Khaled Layouni, Fontainebleau (FR); Balamurugan Meenakshi Sundaram, Painted Post, NY (US); Jong Se Park, San Jose, CA (US); Yousef Kayed Qaroush, Painted Post, NY (US); David Evan Robinson, Corning, NY (US); Jason Scott Stewart, Hornell, NY (US)

(21) Appl. No.: 17/926,858

(22) PCT Filed: May 18, 2021
(86) PCT No.: PCT/US2021/032842

§ 371 Date: Nov. 21, 2022

Related U.S. Application Data
(60) Provisional application No. 63/030,406, filed on May 27, 2020.

(51) Int. Cl. B60K 37/04; H10K 59/10

(52) U.S. Cl. CPC B60K 37/04; H10K 59/10; B60K 2370/63; B60K 2370/67; B60K 2370/691; B60K 2370/81; B60K 2370/95; B60K 2370/48; B60K 2370/693

(57) ABSTRACT

Disclosed are structural design solutions for flexible display panels for use in automobile interiors that comprises a flexible joint portion that are configured to meet the requirements of the automobile industry standard head form impact testing.

### CROSS-REFERENCE TO RELATED APPLICATIONS

This application claims the benefit of priority under 35 U. S.C. § 119 of U.S. Provisional Application Ser. No. 63/030,406 filed on May 27, 2020, the content of which is relied upon and incorporated herein by reference in its entirety.

### BACKGROUND

In the automotive industry, more and more attention has been recently drawn to the improvement of structural crashworthiness for reducing occupant fatalities and injuries. Crashworthiness, it refers to the response a vehicle when it is involved in or undergoes an impact. During the impact, severe injuries could happen if the head of driver or passenger hits the car interior structures, such as display module. Furthermore, if the cover glass is broken, it is very likely to cause secondary injuries (lacerations) from the fragments. To mitigate the injuries and save life while taking full advantage of the high strength glasses used for the cover glass, it is of great importance to find out an optimal display module design that can protect the driver and passengers under moderate impact as required in auto industry specifications. The image-displaying screen material for these displays can be of various types e.g. LED-LCD, TFT-LCD, OLED, AMOLED, LED, PDP, QLED etc. and the design of the entire display assembly is decided based on this material. Typically, OLED (organic light emitting diode) displays are much thinner and flexible compared to conventional LCD (Liquid crystal display). This means that while using OLED, there is more room for creative curved displays whose shape can be dynamically changed in the car. To provide safe interior environment for the passengers in automobiles, the automotive industry uses a head form impact test (HIT). HIT is a mandatory regulation in the automotive sector under FMVSS 201. This test is used to simulate a passenger head impacting various parts of an automobile dashboard to evaluate the safety of the various parts of the automobile dashboard.

Therefore, structural design solutions for automobile dashboard components such as display panels that can meet the requirements of HIT are desired.

### SUMMARY

Disclosed herein are structural design solutions for flexible display panels, such as organic light emitting diodes (OLED) display panels, that comprises a flexible joint portion. A requirement for HIT includes a continuous 3 ms head deceleration of not more than 80 times the gravitational acceleration (80 g). One aspect of the present disclosure is to provide structural design solutions for a display panel's back structure to deform in such a way so as to meet the requirements of HIT and prevent cover glass breakage.

The present disclosure provides some structural design solutions that can enable a display panel that comprises a flexible joint section, such as a living hinge, to pass the requirements of HIT and prevent cover glass failure as well.

Additionally, the present disclosure provides a back structure stiffness design system for partially supported, unsupported and supported displays. Flexible displays include those made with OLED or any other such technology which makes for very thin structure and can be bent easily. Thus this invention is a method of designing a structure for the display to survive HIT without cover glass breakage, where the display is made of flexible material. Since, flexible displays are not used in automobiles in general, this invention also claims the use of flexible displays in the automobiles.

The invention is a series of product improvement designs for a new product (the living hinge). The designs are all modifications or additions to the hinge, its drive mechanism, and other components in the living hinge system which are intended to improve overall HIT performance.

### BRIEF DESCRIPTION OF THE DRAWINGS

These figures are provided for the purposes of illustration, it being understood that the embodiments disclosed and discussed herein are not limited to the arrangements and instrumentalities shown. The figures are schematic and they are not to scale. They are not intended to show dimensions or actual proportions.

FIGS. 1A-B show flowcharts illustrating the methods for providing the stiffness design guideline for a support structure for a flexible display for mounting on a dashboard of an automobile to meet the requirement of the HIT according to the present disclosure.

FIG. 2 is a cross-sectional illustration of a general structure of an OLED display panel.

FIG. 3 is an illustration of a general setup of HIT.

FIG. 4 shows illustrations showing some examples of flexible display panel shapes.

FIG. 5A-5D are illustrations representing linear and rotational springs and dampers.

FIG. 6 is an illustration representing a continuous back support for flexible OLED display.

FIG. 7 is an exploded view illustration showing flexible OLED display and back support structure in a HIT setup.

FIG. 8 is a plot of Rotational spring stiffness (K2) v. Linear spring stiffness (K1) illustrating the desired design window for the back support structure for the flexible OLED display.

FIGS. 9A-9B are illustrations of a flexible OLED display panel showing an example of a strap that is attached to the backside of the OLED display panel for limiting the distance the living hinge portion of the OLED display panel can travel during HIT.

FIG. 10 is an illustration of a flexible OLED display panel that comprises a dampened actuation mechanism according to an embodiment of the present disclosure.

FIG. 11 is an illustration of a flexible OLED display panel that comprises a shock absorber mechanism according to an embodiment of the present disclosure.

FIG. 12 is an illustration of an embodiment of a structure that dampens the impact force applied to the flexible OLED display panel during HIT.

FIGS. 13A-13H are illustrations showing another embodiment of a structure that dampens the impact force applied to the flexible OLED display panel during HIT.

FIGS. 14A-14D are illustrations showing another embodiment of a structure that dampens the impact force applied to the flexible OLED display panel during HIT.

FIGS. 15A-15B are illustrations showing another embodiment of a structure that dampens the impact force applied to the flexible OLED display panel during HIT.

While this description can include specifics, these should not be construed as limitations on the scope, but rather as descriptions of features that can be specific to particular embodiments.

### DETAILED DESCRIPTION

Unless otherwise specified, terms such as “top,” “bot tom,” “outward,” “inward,” and the like are words of convenience and are not to be construed as limiting terms. In addition, whenever a group is described as comprising at least one of a group of elements and combinations thereof, the group can comprise, consist essentially of, or consist of any number of those elements recited, either individually or in combination with each other.

Similarly, whenever a group is described as consisting of at least one of a group of elements or combinations thereof, the group can consist of any number of those elements recited, either individually or in combination with each other. Unless otherwise specified, a range of values, when recited, includes both the upper and lower limits of the range. As used herein, the indefinite articles “a,” and “an,” and the corresponding definite article “the” mean “at least one” or “one or more,” unless otherwise specified.

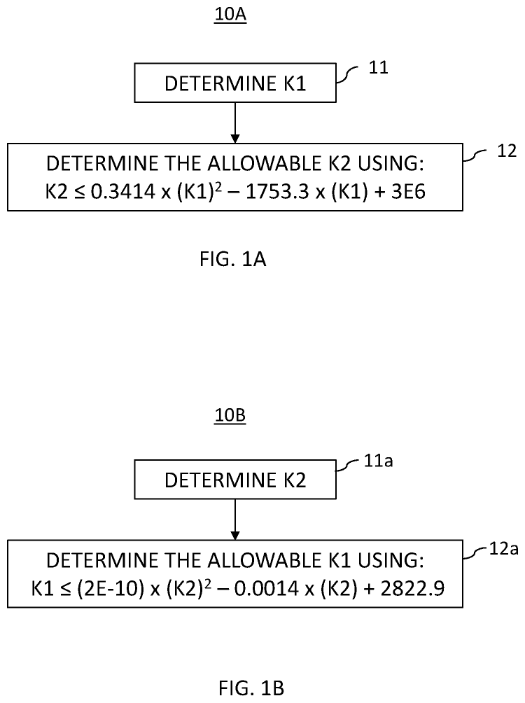

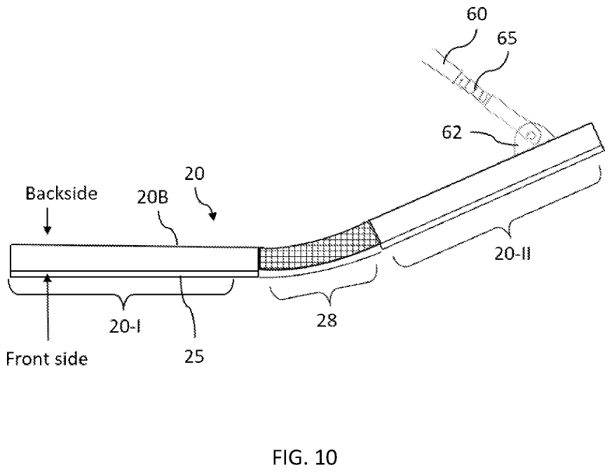

A system for determining the stiffness of a display panel back structure that would meet the requirement of HIT is disclosed. The system comprises a processor capable of executing instructions; and a non-transitory, machine readable storage medium encoded with program instructions for providing a stiffness design guideline for a support structure for a flexible display for mounting on a dashboard of an automobile to meet the requirement of the HIT, such that when the processor executes the program instructions, the processor performs one of the methods outlined in FIGS. 1A-1B. The method can be implemented in two different embodiments as illustrated by the flowchart 10A in FIGS. 1A and 10B in FIG. 1B. In the first embodiment, the method comprises: (a1) determining linear spring stiffness K1 of the support structure (step 11); and (a2) determining the allowable rotational spring stiffness K2 of the support structure by using the following relationship: K2≤0.3414×(K1)²−1753.3×(K1)+3E6. (step 12). In the second embodiment, the method comprises: (b1) determining rotational spring stiffness K2 of the support structure (step 11a); and (b2) determining the allowable linear spring stiffness K1 of the support structure by using the following: K1≤(2E−10)×(K2)²−0.0014×(K2)+2822.9. (step 12a).

According to another aspect, a non-transitory, machine readable storage medium is disclosed. The machine readable storage medium is encoded with program instructions for providing the stiffness design guideline for a support structure fora flexible display for mounting on a dashboard of an automobile to meet the requirement of the HIT, such that when a processor executes the program instructions, the processor performs the method outlines in FIG. 1. The method can be implemented in two different embodiments as illustrated by the flowchart 10A and 10B as discussed above.

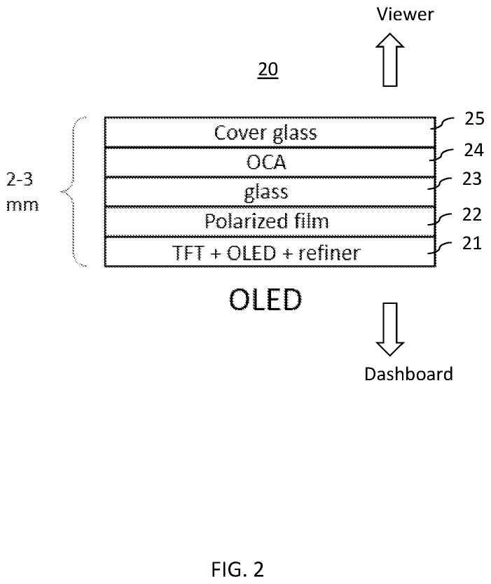

The disclosed method implemented by the system described above is applicable to a version of a living hinge portion of a flexible display panel structure that has the general layered structure 20 shown in FIG. 2. Some examples of the flexible display panel are OLED type displays and LCD type displays. In the illustrated example that includes an OLED display structure, the TFT+OLED+refiner layer 21 produces the display image and is protected by a cover glass 25 on the viewer side. Between the TFT+OLED+refiner layer 21 and the cover glass 25, the OLED display generally has a polarized film 22, a glass layer 23, and an optically clear adhesive (OCA) layer 24 that holds the cover glass 25 in place. LCD type displays generally require more functional layers, such as back-lighting layer, and thus are generally thicker than OLED type displays.

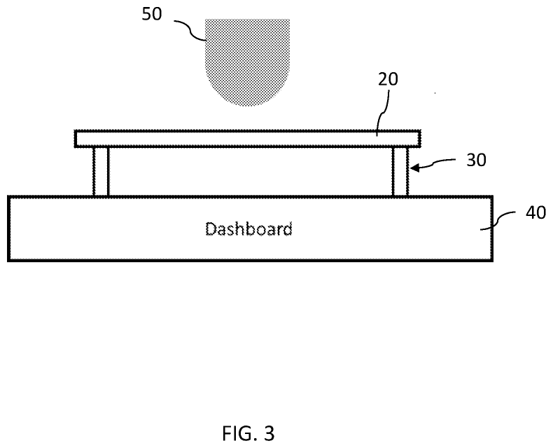

FIG. 3 is a generic schematic of a typical display assembly in an automobile. In the assembly, a display panel structure 20 is attached to a dashboard 40. To attach the display panel structure 20 to the dashboard 40, some type of supporting structure 30 (referred to hereinafter as “back structure”) attaches the backside of the display panel (i.e., the side opposite of the cover glass 25) structure 20 to the dashboard 40. In the example shown in FIG. 3, the back structure 30 comprises a set of holding brackets. FIG. 3 also shows the head form 50 that is used for the HIT. The head form 50 is typically 165 mm in diameter and has a mass of 6.8 kg. This head form can impact the display at different angles and typically at a speed of 6.67 m/s. The total impact energy for this test is around 152 Joules. The flexible display is mounted to the dashboard 40 using the back structure 30 which can be made of metal, plastic or any such typical automotive grade material. For HIT, the dashboard part includes the use of an actual dashboard sample and/or some structural frame (e.g. cross beam) to mount the back structure 30.

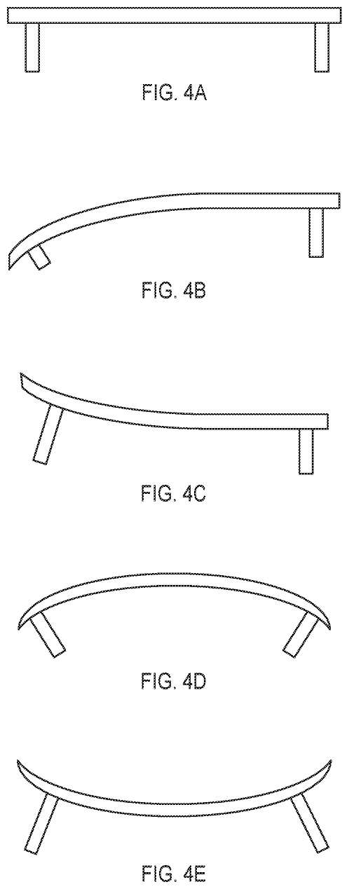

FIG. 4 shows some examples of potential shapes (a)-(e) into which a flexible display can conform. Typically once a shape is set, the display is installed in that position. However, the inventive system, method, and structures of the present disclosure are applicable to flexible displays whose shapes can be dynamically changed in the car after installation. This means the user will be able to orient the display from flat to convex or concave and vice versa at any time. Thus, such flexible display panels have a flexible portion that allows the display panel to be dynamically flexed. The flexible portion can be a living hinge for example. Thus, the term dynamically flexible or bendable means that the display panel can be flexed back and forth between two different radii of curvature. The living hinge configuration also requires that the cover glass 25 layer is also capable of being dynamically flexed. The term “cover glass” as used herein can be a variety of different materials and is not limited to a glass. More discussion on the cover glass 25 will be provided below in the Cover Glass section.

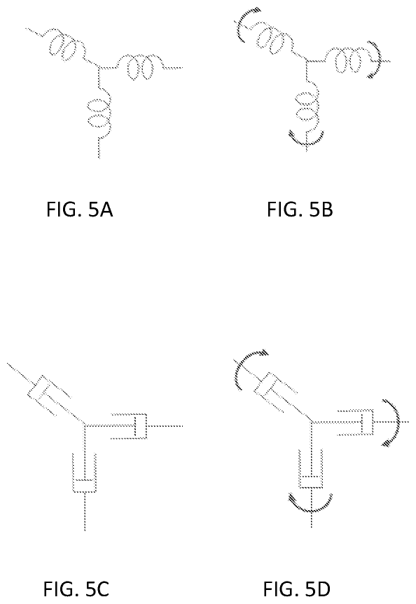

The back structure 30 for the flexible display is typically made of metal and/or plastic and should have some stiffness value associated with it. This stiffness value determines the behavior of the entire display panel during HIT. The stiffness can be approximated by linear springs, linear dampers, rotational spring and rotary dampers acting individually or in a combination. FIG. 5A-5D are simple graphic illustrations representing the linear springs (FIG. 5A), rotational springs (FIG. 5B), linear dampers (FIG. 5C), and rotational dampers (FIG. 5D).

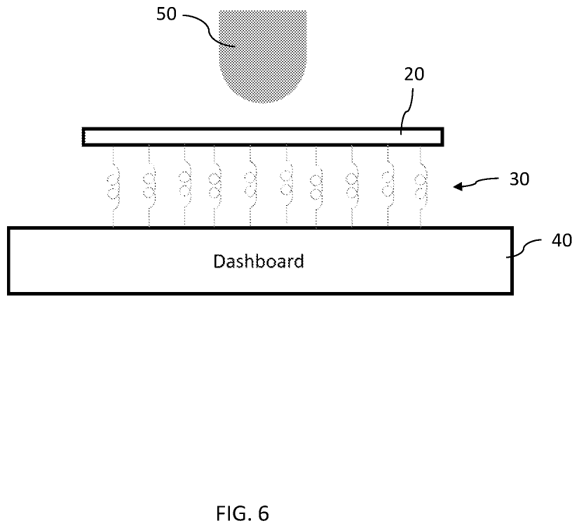

FIG. 6 is an illustration representing an example in which the flexible display panel 20 is attached to the dashboard 40 a continuously supporting back structure 30. An example of a continuously supporting back structure 30 is a sheet or a padding of a resilient material. The sheet of resilient material is graphically represented as an array of springs that approximates the stiffness of the back structure 30 in FIG. 6.

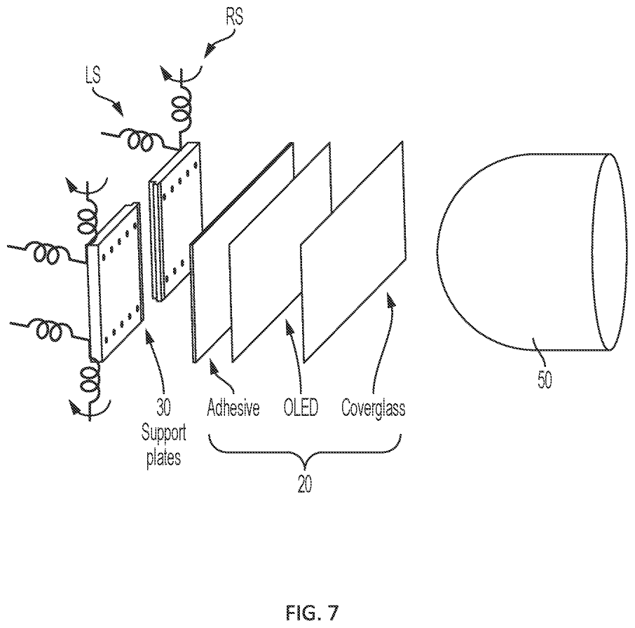

FIG. 7 shows the exploded view of the model of a display panel 20 used for Finite Element (FE) simulations of HIT. Although any number of combinations of the springs can be used to represent a back structure stiffness, as an example here a combination of one linear spring LS and one rotational spring RS at each of the four corner of the OLED display panel is used in the FE model simulation.

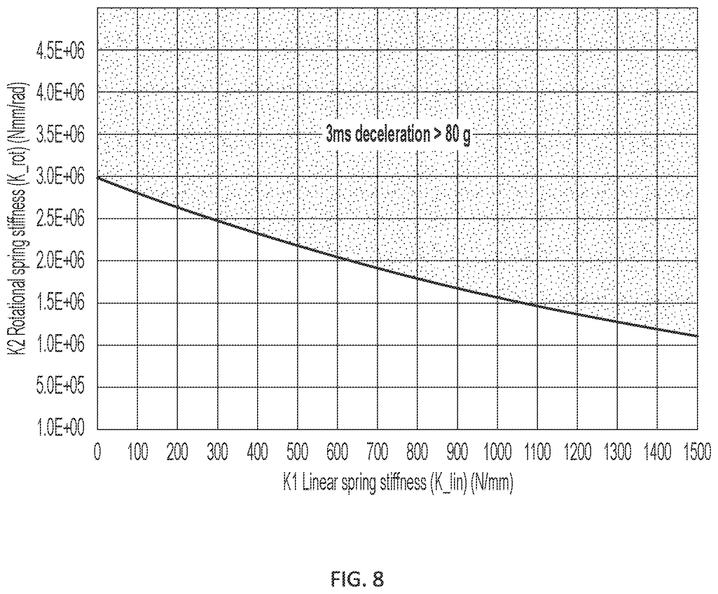

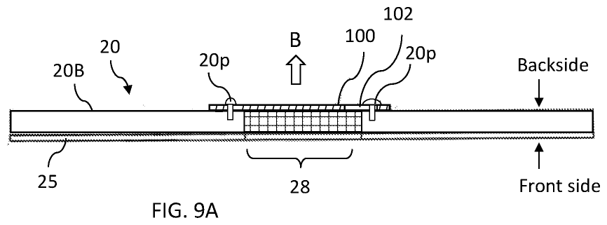

The FE model of the OLED display assembly shown in FIG. 7 resulted in defining a quantitative relationship between the rotational spring stiffness K2 and the linear spring stiffness K1. This relationship is defined by the curve shown in the K2 v. K1 plot of FIG. 8. HIT. The plot represents the spring stiffness relationship for only one set of springs in one corner of the OLED display panel (i.e. a quarter symmetry model). As noted in FIG. 8, the region below the plot line represents the K2, K1 pair that will meet the requirements of HIT. Thus, this model provides a design guideline for designing the back structure 30. FIGS. 9A-9B are illustrations of a flexible display panel 20 showing an example of a strap 100 that is attached to the backside of the flexible display panel for limiting the distance the living hinge portion 28 of the flexible display panel 20 can travel during HIT. FIG. 9A is a sectional view taken through the section line A-A shown in FIG. 9B. FIG. 9B is a plan view of the backside of the flexible display panel 20. As mentioned earlier, the living hinge portion 28 of the flexible display panel 20 may or may not include the display layers depending on the lay out of the display portions of the flexible display panel 20.

According to some embodiments, the flexible display panel 20 has a front side and a backside and comprises a cover glass 25 on the front side, a back plate 20B on the backside, and a living hinge portion 28. The cover glass 25 and the back plate 20B in the living hinge portion are flexible allowing the flexible display panel 20 to bend at the living hinge 28. The display panel 20 can comprise one or more of the straps 100 depending on the configuration of the particular flexible display panel and the stiffness of the strap material chosen. Each of the strap 100 spans across the living hinge portion 28 and is attached to the back plate 20B on either sides of the living hinge portion. In the illustrated example, the strap 100 is attached to the back plate 20B by a pair of attachment pins 20p. The strap 100 is made from a material that is stiffer than the living hinge portion 28 of the flexible display panel 20 such that the strap provides a predetermined amount of resistance to the living hinge portion from bending When the impact force from HIT is applied to the front side of the display panel 20, the force pushes the living hinge portion 28 backwards (direction of the arrow B in FIG. 9A) and the two attachment pins 20p move away from each other and apply tension (represented by the arrows T) on the strap 100. The strap 100 provides resistance against the tension and limits the distance the living hinge can travel backwards. The strap 100 can do this in two ways. One is that the stiffness of the strap 100 provides resistance against the bending of the living hinge portion 28 when the living hinge portion is being forced to move in the direction B. The other is by resisting against being stretched by the tension T being applied by the attachment pins 20p.

The strap 100 is attached to the back plate 20B on one side of the living hinge portion 28 so that there is no relative movement between the strap and the back plate, and the strap is attached to the other side of the living hinge portion 28 in a manner that allows some sliding movement between the strap and the back plate. As shown in FIG. 9B, this sliding movement is enabled by a slot 102 that is provided on one end of the strap 100. The sliding movement is along the length of the strap 100. The sliding movement allows the flexible display panel 20 to bend in the intended direction without any resistance. In the illustrated example, the display panel 20 is intended to be flexed between the flat configuration as shown and a bent configuration in which the living hinge 28 is bent so that the front side of the living hinge 28 becomes convex. To transition from the flat configuration to the bent configuration, the living hinge portion 28 would move out in the direction opposite of the arrow B shown in FIG. 9A and the two attachment pins 20p will move toward each other. Referring to FIG. 9B, the slot 102 in the strap 100 will allow the attachment pin 20p on the right-hand side of the figure to freely move from the end a of the slot 102 toward the end b of the slot 102 without encountering any resistance.

In some embodiments of the flexible display panel 20, the predetermined amount of resistance to bending provided by the strap is sufficient to limit the bending of the living hinge portion 28 to a predetermined amount when an impact force that is equivalent to a head form impact test is exerted on the living hinge portion 28 from the front side. In a HIT, the impact force is equivalent to an impact force exerted by a 6.8 kg head form traveling at 6.67 meters/second on the living hinge portion.

In some embodiments of the flexible display panel 20, the predetermined amount of resistance to bending provided by the strap 100 is sufficient to limit the bending of the living hinge portion so that the 6.8 kg head form traveling at 6.67 meters/second impacting the living hinge portion would decelerate at a rate not more than 80 g over a 3 ms period, wherein g is the gravitational acceleration. This is equivalent to the impact force applied during an HIT.

The strap 100 can be made of any suitable material that can be made into an appropriate dimension that would result in the desired stiffness. In some embodiments of the flexible display panel 20, each of the one or more straps 100 can be sized to be attached to the back plate 20B with one pair of attachment pins 20p. In some other embodiments, each of the one or more straps 100 can be wider than the example shown in FIG. 9B and can be attached to the back plate 20B by more than one pair of attachment pins 20p.

FIG. 10 is an illustration of a flexible display panel 20 according another embodiment. The flexible display panel 20 has a front side and a backside and comprises a first portion 20-I, a second portion 20-II, a living hinge portion 28 connecting the first portion 20-I and the second portion 20-II. The first portion 20-I is affixed to a fixed structure, such as the dashboard of an automobile, and the second portion 20-II is movable with respect to the first portion 20-I by operation of the living hinge portion 28. An actuating rod 60 is hingeably attached to the backside of the second portion 20-II for actuating the movement of the second portion with respect to the first portion. Generally, the actuating rod 60 mechanism would be driven by a remotely activated driving unit such as an electric motor for moving the second portion 20-II to put the display panel 20 in a desired configuration. For example, the actuating rod 60 can be attached to the back panel 20B by a hinge 62. The actuating rod 60 comprises a damper assembly 65 that is configured for providing a predetermined amount of resistance to the second portion from being forced backward by an impact force applied from the front side.

In some embodiments, the predetermined amount of resistance provided by the damper assembly 65 is sufficient to dampen the impact force that is equivalent to an impact force applied during an HIT and meet the requirements of the HIT described herein.

Some examples of the damper assembly 65 can be a liquid-filled shock absorber, a gas-filled shock absorber, or a coil spring. The damper assembly 65 arrangement can work in a flexible OLED display panel system that has normally convex or concave on the front side.

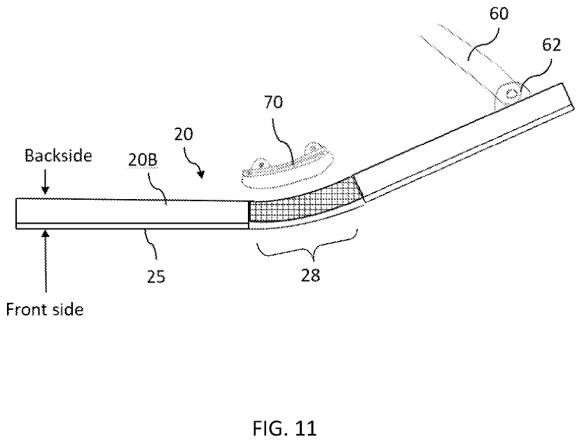

FIG. 11 is an illustration of a flexible display panel that comprises a shock absorber mechanism according to some embodiments. The flexible display panel 20 has a front side and a backside. The display panel 20 comprises a cover glass 25 on the front side, a back plate 20B on the backside, and a living hinge portion 28, where the cover glass and the back plate in the living hinge portion are flexible. The flexible display panel 20 also comprises a shock absorber 70 provided in proximity to the backside of the living hinge portion 28 and mounted to a fixed structure such as the dashboard. The shock absorber 70 provides a predetermined amount of resistance to the living hinge portion from being forced backward by an impact force applied from the front side that is equivalent to the impact force applied during HIT and meet the requirements of the HIT described herein.

In some embodiments, where the flexible display panel 20 is a display panel in an automobile that is equipped with a main air bag system that deploys when the automobile is in a collision, the shock absorber 70 can be an air bag that is synchronized to be deployed at the same time as the main air bag system. The shock absorber 70 can also be made of a compliant material such as springs, pads, etc. The shock absorber 70 arrangement can work in a flexible OLED display panel system that has normally convex or concave on the front side.

In some embodiments of the flexible display panel 20 having the actuating rod 60 attached to the backside of the second portion 20-II by a hinge 62, the hinge 62 can be configured to lock or provide a predetermined amount of resistance to the second portion 20-II from being forced backward and rotate about the hinge 62 by an impact force applied from the front side somewhere between the hinged joint and the first portion by resisting rotation of the second portion about the hinged joint. The predetermined amount of resistance provided by the hinged joint is sufficient to dampen the impact force that is equivalent to an impact force exerted during HIT and meet the requirements of HIT.

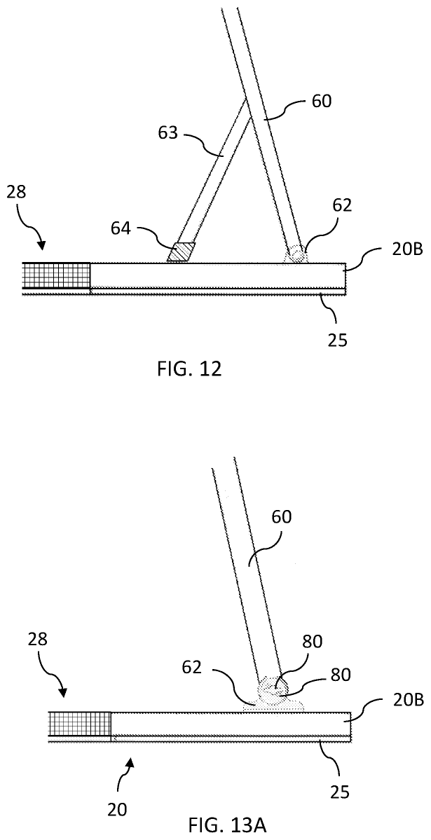

Referring to FIG. 12, in some embodiments, the actuating rod 60 can comprise a supporting rod 63 provided on the actuating rod 60 that extends toward and contacts the back plate 20B at a point between the hinged joint and the living hinge portion 28. The supporting rod braces against the second portion 20-II of the display panel and prevents it from rotating about the hinged joint 62 more than a predetermined amount when a force is applied to the living hinge portion from the front side of the display panel. The supporting rod 63 can be attached to the actuating rod 60 and functions as a brace between the actuating rod 60 and the back plate 20B so that forces closer to the hinge 62 are transferred back into the actuating rod 60, thus limiting the length of the travel by the second portion 20-H during HIT. The supporting rod 63 can be provided with a piece of damper material 64 at the end of the supporting rod 63 where it contacts the back plate 20B to dampen the impact force during HIT.

In some embodiments, the hinge 62 comprises a gear assembly configured to provide the predetermined amount of resistance.

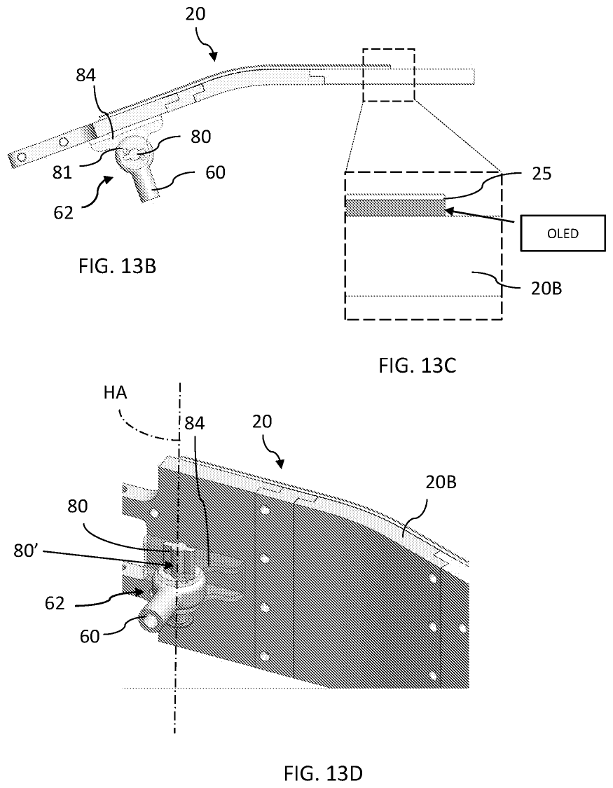

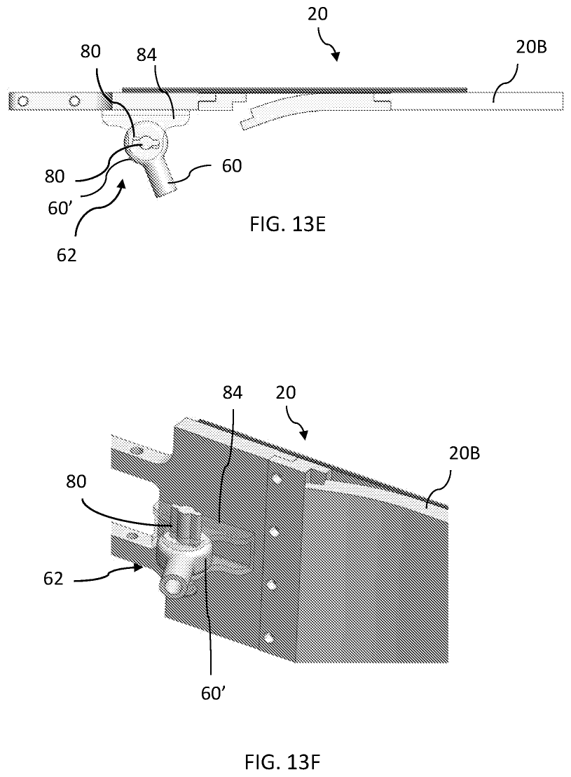

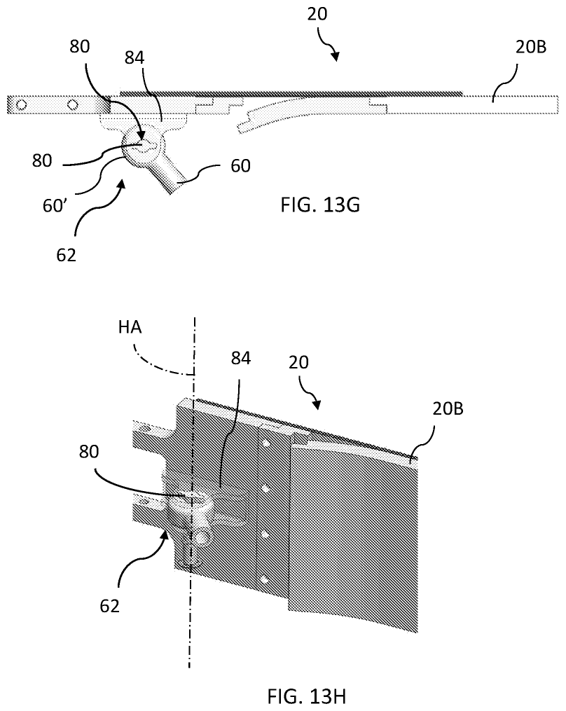

Referring to FIGS. 13A-13H, the display panel 20 where the actuating rod 60 is attached to the back plate 20B by a hinge 62, the hinge can comprise a locking hinge pin 80 that locks the hinged joint and provides the predetermined amount of resistance that is sufficient to prevent the second portion from being rotated about the hinged joint beyond a predetermined amount when said impact force is applied.

In some embodiments, the locking hinge pin 80 comprises a keyed head portion 80′. The locking hinge pin 80 is configured to be movable along the hinge axis HA between an unlocked position and a locked position. When the applied impact force causes the second portion of the display panel to rotate about the hinged joint more than a predetermined amount, the hinge pin moves into its locked position preventing the second portion from rotating any further.

The hinge 62 comprises a hinge bracket 84 that holds the terminal end of the actuating rod 60 between a pair of flanges. The hinge bracket 84 and the terminal end 60′ of the actuating rod 60 are provided with holes that align along the hinge axis HA. The locking hinge pin 80 extends through the holes in the hinge bracket 84 and the terminal end 60′ of the actuating rod 60 to hold the components together as a hinged joint. To enable the locking function of the locking hinge pin 80, the holes in the hinge bracket 84 and the hole in the terminal end 60′ of the actuating rod 60 are key holes that are shaped to receive the particular shape of the keyed head portion 80′ of the locking hinge pin 80. FIG. 13E shows the winged shape of the keyed head portion 80′ of the hinge pin 80. Normally, in the hinge 62 assembly is in an unlocked position shown in FIGS. 13B, 13D, 13E, and 13F. In the unlocked position, the key holes in the hinge bracket 84 and the terminal end 60′ of the actuating rod 60 are offset and are not aligned. The keyed head portion 80′ of the hinge pin sits within the key hole in the upper flange of the hinge bracket 84 but because the key hole in the terminal end 60′ of the actuating rod 60 is offset, the keyed head portion 80′ will not drop into the terminal end 60′ of the actuating rod 60. This unlocked configuration of the hinge 62 allows the second portion 20-II to rotate about the hinge axis HA.

If the second portion 20-II rotates to a predetermined position as shown in FIGS. 13G-13H, however, the key holes of the hinge bracket 84 and the terminal end 60′ of the actuating rod 60 come into alignment. This allows the keyed head portion 80′ of the hinge pin 80 to now drop into the key hole in the terminal end 60′ of the actuating rod 60. Thus, the hinge pin 80 moves from its unlocked position into its locked position. As shown in the isometric view in FIG. 13H, when the hinge pin 80 is in the locked position, the keyed head portion 80′ does not completely drop into the key hole in the actuating rod 60. At least a part of the keyed head portion 80′ still remains in the key hole in the upper flange of the hinge bracket 84 so that the keyed head portion 80′ is in both key holes. This prevents the hinge bracket 84 (which is affixed to the back plate 20B) and the terminal end 60′ of the actuating rod 60 from rotating relative to one another.

Preferably, the locking hinge pin 80 is configured with a spring-loaded mechanism (not shown) that is constantly urging the keyed head portion 80′ of the hinge pin 80 toward its locking position so that when the key holes in the hinge bracket 84 and the terminal end of the actuating rod 60 do come into alignment, the keyed head portion 80′ of the hinge pin 80 drops into the key hole in the terminal end 60′ of the actuating rod automatically and lock the hinge 62.

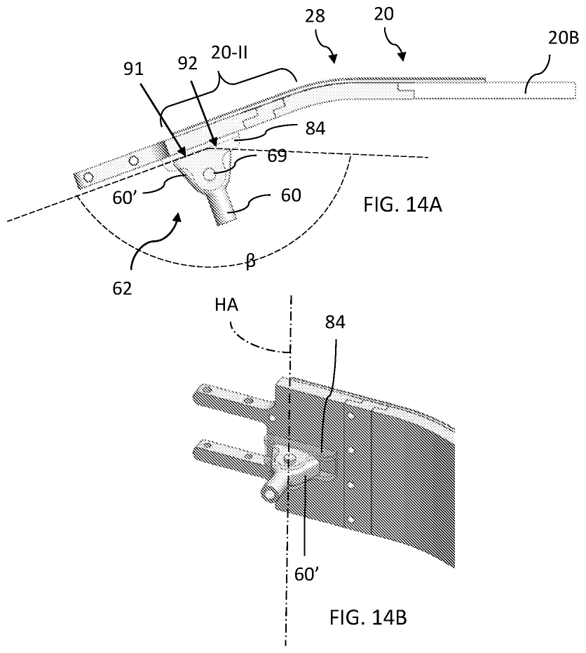

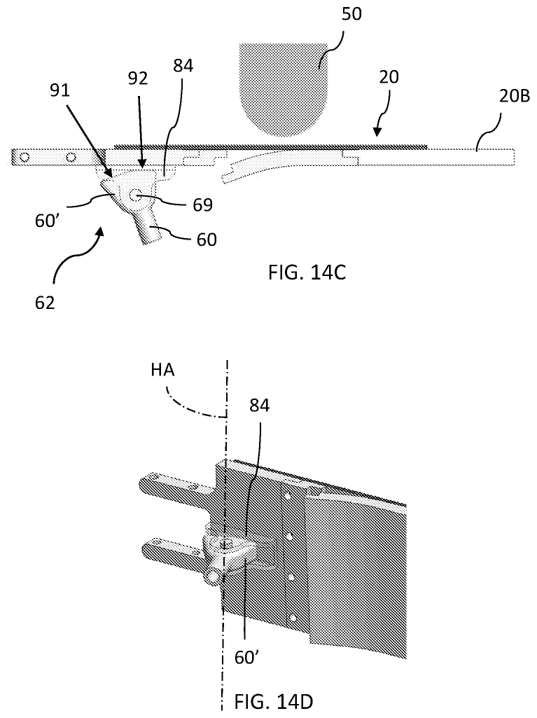

Referring to FIGS. 14A-14D, in another embodiment, the hinge 62 can be configured to limit the rotation of the second portion 20-II of the display panel about the hinge 62 by configuring the terminal end 60′ of the actuating rod 60 to have two flat portions that are angled at a predetermined angle β that operate as stops that prevent the second portion 20-II from rotating about the hinge axis HA beyond a predetermined range. As shown, the terminal end 60′ of the actuating rod 60 is configured with flat surfaces 91, 92 that are oriented at the predetermined angle β. Each of the flat surfaces act as a stop by butting up against the back plate 20B when the flexible display panel 20 rotates beyond a predetermined amount in either direction. In FIG. 14A, the actuating rod 60 has pulled the second portion 20-II of the flexible display panel 20 backward holding the flexible display 20 bent at the living hinge portion 28. The first flat surface 91 is in contact with the backside of the back plate 20B. In FIG. 14D, shows a configuration after the head form 50 has impacted the flexible display panel 20 at its living hinge portion 28 causing the living hinge 28 to travel backward and straighten out. This has caused the second portion 20-II of the display to rotate about the hinge pin 69 so that now the second flat surface 92 on the terminal end 60′ of the actuating rod 60 is in contact with the backside of the back plate 20B. The second flat surface 92 functions as a stop and prevents the second portion 20-II of the flexible display panel 20 from rotating any further. This feature can be utilized to limit the travel of the living hinge portion 28 upon impact by the head form 50, dampening the impact force and assist in meeting the requirement of HIT.

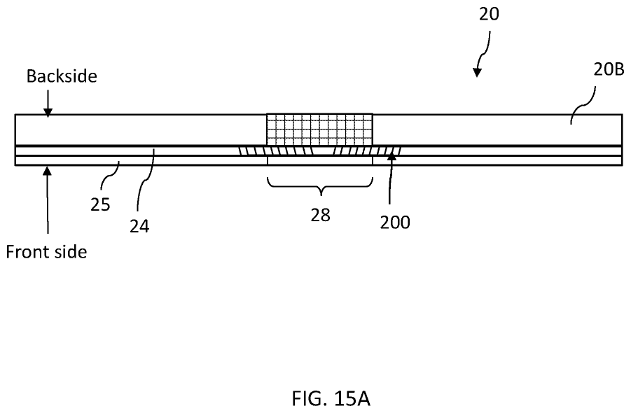

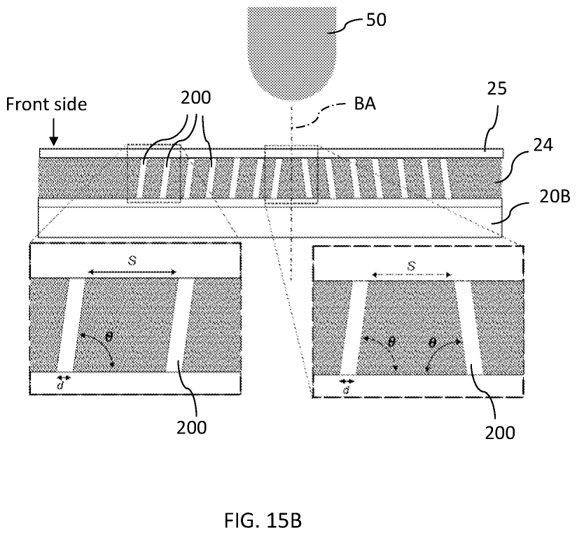

Referring to FIGS. 15A-15B, according to another aspect, a plurality of perforations 200 can be provided in the optically clear adhesive (OCA) layer 24 (see FIG. 2) in the living hinge portion 28 of the flexible display panel 20 to provide the dampening effect needed to meet the requirements of HIT. In the structures that fail the requirements of HIT, one of the observed causes of high deceleration is the immediate impulse response from the cover glass 25 in the first few milliseconds of the impact. The plurality of perforations in the OCA layer 24 can allow the cover glass 25 to travel further in the region of the impact and reduce the rate of deceleration.

According to some embodiments, the flexible display panel 20 having a front side and a backside can comprise a cover glass 25 on the front side, a back plate 20B on the backside, an adhesive layer 24 between the cover glass 25 and the back plate 20B, and a living hinge portion 28. The cover glass, the adhesive layer, and the back plate in the living hinge portion are flexible. The adhesive layer 24 has a thickness and the adhesive layer in the living hinge portion 28 comprises a plurality of perforations 200 extending through the thickness of the adhesive layer 24. The perforations 200 in the adhesive layer allows the portion of the cover glass 25 in the living hinge portion 28 to travel further during the impact imposed on the living hinge portion 28 during HIT, which reduces the deceleration rate of the head form 50.

In some embodiments, each of the perforations 200 can be spaced apart by a spacing S from its nearest neighboring perforation. The spacing S can be 10 μm to 50 mm. In some embodiments, each of the perforations 200 can have a cylindrical shape having a diameter d that is 5 μm to 10 mm. In some embodiments, the perforations 200 can be oriented at an angle θ that is 70° to 120° with respect to the back plate. In some embodiments, the perforations 200 can be oriented in the same directions. In some embodiments, all of the perforations 200 can be oriented in random orientation. In some embodiments, an axis of bending BA is defined within the living hinge portion 28 and the perforations 200 can be oriented at an angle θ that is 70° to 120° with respect to the back plate 20B and some of the plurality of perforations 200 can be oriented toward the axis of bending BA. In some embodiments, the perforations 200 on one side of the axis of bending BA can be oriented at an angle θ of a first value and the perforations 200 on the opposite side of the axis of bending BA can be oriented at an angle θ of a second value. In some embodiments the first value and the second value can be the same. In other words, the arrangement of the perforations 200 is symetrical about the axis of bending BA. In some embodiments, the first value and the second value can be different. In other words, the arrangement of the perforations 200 can be asymetric about the axis of bending BA. In some embodiments, the angle θ for each of the perforations 200 can be randomly distributed within the range of 70° to 120°.

### Cover Glass

In one or more embodiments, the cover glass 25 can include an amorphous substrate, which may include a glass article. The glass article may be strengthened or non-strengthened. Examples of suitable glass composition families used to form the glass articles include soda lime glass, alkali aluminosilicate glass, alkali containing borosilicate glass and alkali aluminoborosilicate glass. In one or more alternative embodiments, the cover glass 25 can include crystalline substrates such as glass ceramic article (which may be strengthened or non-strengthened) or can include a single crystal structure, such as sapphire. In one or more specific embodiments, the cover glass 25 includes an amorphous base (e.g., glass) and a crystalline cladding (e.g., sapphire layer, a polycrystalline alumina layer and/or or a spinel (MgAl₂O₄) layer).

The cover glass 25 can be substantially sheet-like, although other embodiments can utilize a curved or otherwise shaped or sculpted substrate. The cover glass 25 can be substantially optically clear, transparent and free from light scattering. In such embodiments, the cover glass 25 may exhibit an average light transmission over the optical wavelength regime of about 85% or greater, about 86% or greater, about 87% or greater, about 88% or greater, about 89% or greater, about 90% or greater, about 91% or greater or about 92% or greater. In one or more alternative embodiments, the cover glass 25 may be opaque or exhibit an average light transmission over the optical wavelength regime of less than about 10%, less than about 9%, less than about 8%, less than about 7%, less than about 6%, less than about 5%, less than about 4%, less than about 3%, less than about 2%, less than about 1%, or less than about 0%. In some embodiments, these light transmittance values are total transmittance values (taking into account transmittance through both major surfaces of the substrate) The cover glass 25 may optionally exhibit a color, such as white, black, red, blue, green, yellow, orange etc.

In one or more embodiments, the cover glass 25 may be curved such that it exhibits a radius of curvature in a range from about 20 mm to about 10,000 mm, from about 20 mm to about 9,000 mm, from about 20 mm to about 8,000 mm, from about 20 mm to about 7,000 mm, from about 20 mm to about 6,000 mm, from about 20 mm to about 5,000 mm, from about 20 mm to about 4,000 mm, from about 20 mm to about 3,000 mm, from about 20 mm to about 2,000 mm, from about 20 mm to about 1,000 mm, from about 20 mm to about 750 mm, from about 20 mm to about 500 mm from about 20 mm to about 250 mm, from about 50 mm to about 10,000 mm, from about 75 mm to about 10,000 mm, from about 100 mm to about 10,000 mm, from about 200 mm to about 10,000 mm, from about 300 mm to about 10,000 mm, from about 400 mm to about 10,000 mm, from about 500 mm to about 10,000 mm, from about 600 mm to about 10,000 mm, from about 700 mm to about 10,000 mm, from about 800 mm to about 10,000 mm, from about 900 mm to about 10,000 mm, from about 1,000 mm to about 10,000 mm, from about 1,100 mm to about 10,000 mm, from about 1,200 mm to about 10,000 mm, from about 1,300 mm to about 10,000 mm, from about 1,400 mm to about 10,000 mm, from about 1,500 mm to about 10,000 mm, from about 1,600 mm to about 10,000 mm, from about 1,700 mm to about 10,000 mm, from about 1,800 mm to about 10,000 mm, from about 1,900 mm to about 10,000 mm, from about 2,000 mm to about 10,000 mm, from about 2,100 mm to about 10,000 mm, from about 2,200 mm to about 10,000 mm, from about 2,300 mm to about 10,000 mm, from about 2,400 mm to about 10,000 mm, from about 2,500 mm to about 10,000 mm, from about 3,000 mm to about 10,000 mm, from about 3,500 mm to about 10,000 mm, from about 4,000 mm to about 10,000 mm, from about 5,000 mm to about 10,000 mm, from about 7,500 mm to about 10,000 mm, from about 20 mm to about 1,000 mm, from about 500 mm to about 5000 mm, from about 500 mm to about 2500 mm, from about 500 mm to about 1500 mm, from about 500 mm to about 1000 mm, from about 250 mm to about 3000 mm, from about, or from about 400 mm to about 10,000 mm.

In one or more embodiments, the cover glass 25 is curved and comprises a cold-bent cover glass 25. As used herein, the terms “cold-bent,” or “cold-bending” refers to curving the cover glass 25 at a cold-bend temperature which is less than the softening point of the glass. Often, the cold-bend temperature is room temperature. The term “cold-bendable” refers to the capability of a cover glass 25 to be cold-bent. In one or more embodiments the cold-bent cover glass 25 may comprise a glass article or glass ceramic article, which may optionally be strengthened. In more embodiments, a feature of a cold-bent cover glass 25 is asymmetric surface compressive stress between a first major surface and a second major surface. In one or more embodiments, prior to the cold-bending process or being cold-bent, the respective compressive stresses in the first major surface and the second major surface of the cover glass 25 are substantially equal. In one or more embodiments in which the cover glass 25 is unstrengthened, the first major surface and the second major surface exhibit no appreciable compressive stress (CS), prior to cold-bending. In one or more embodiments in which the cover glass 25 is strengthened (as described herein), the first major surface and the second major surface exhibit substantially equal compressive stress with respect to one another, prior to cold-bending. In one or more embodiments, after cold-bending, the CS on the surface having a concave shape after cold-bending increases, while the CS on the surface having a convex shape after cold-bending decreases. In other words, the CS on the concave surface is greater after cold-bending than before cold-bending. Without being bound by theory, the cold-bending process increases the CS of the cover glass 25 being shaped to compensate for tensile stresses imparted during cold-bending. In one or more embodiments, the cold-bending process causes the concave surface to experience compressive stresses, while the surface forming a convex shape after cold-bending experiences tensile stresses. The tensile stress experienced by the convex surface following cold-bending results in a net decrease in surface compressive stress, such that the compressive stress in convex surface of a strengthened cover glass 25 following cold-bending is less than the compressive stress on the same surface when the cover glass 25 is flat.

In one or more embodiments, the cover glass 25 is curved and comprises be a hot-formed cover glass, which is permanently curved and the first major surface and the second major surface have the same CS.

In one or more embodiments, the living hinge portion may flex or bend the cover glass 25 or may cause the cover glass to flex and bend along the bend axis. In one or more embodiments, the cover glass 25 may exhibit a first radius of curvature that is about 10,000 mm or less, and is capable of being dynamically bent along the bend axis. In one or more embodiments, the cover glass 25 can flex or bend between a flat state to a curved state along the bend axis, from the curved state to a flat state along the bend axis, from a first radius of curvature and a second radius of curvature along the bend axis, from a second radius of curvature to the first radius of curvature along the bend axis, and combinations thereof.

In one or more embodiments in which the cover glass 25 can flex or bend between a flat state (in which the radius of curvature is greater than 10,000 mm to infinity) to a curved state, the curved state may have a radius of curvature from about 20 mm to about 10,000 mm, from about 20 mm to about 9,000 mm, from about 20 mm to about 8,000 mm, from about 20 mm to about 7,000 mm, from about 20 mm to about 6,000 mm, from about 20 mm to about 5,000 mm, from about 20 mm to about 4,000 mm, from about 20 mm to about 3,000 mm, from about 20 mm to about 2,000 mm, from about 20 mm to about 1,000 mm, from about 20 mm to about 750 mm, from about 20 mm to about 500 mm from about 20 mm to about 250 mm, from about 50 mm to about 10,000 mm, from about 75 mm to about 10,000 mm, from about 100 mm to about 10,000 mm, from about 200 mm to about 10,000 mm, from about 300 mm to about 10,000 mm, from about 400 mm to about 10,000 mm, from about 500 mm to about 10,000 mm, from about 600 mm to about 10,000 mm, from about 700 mm to about 10,000 mm, from about 800 mm to about 10,000 mm, from about 900 mm to about 10,000 mm, from about 1,000 mm to about 10,000 mm, from about 1,100 mm to about 10,000 mm, from about 1,200 mm to about 10,000 mm, from about 1,300 mm to about 10,000 mm, from about 1,400 mm to about 10,000 mm, from about 1,500 mm to about 10,000 mm, from about 1,600 mm to about 10,000 mm, from about 1,700 mm to about 10,000 mm, from about 1,800 mm to about 10,000 mm, from about 1,900 mm to about 10,000 mm, from about 2,000 mm to about 10,000 mm, from about 2,100 mm to about 10,000 mm, from about 2,200 mm to about 10,000 mm, from about 2,300 mm to about 10,000 mm, from about 2,400 mm to about 10,000 mm, from about 2,500 mm to about 10,000 mm, from about 3,000 mm to about 10,000 mm, from about 3,500 mm to about 10,000 mm, from about 4,000 mm to about 10,000 mm, from about 5,000 mm to about 10,000 mm, from about 7,500 mm to about 10,000 mm, from about 20 mm to about 1,000 mm, or from about 400 mm to about 10,000 mm.

In one or more embodiments in which the cover glass 25 can flex or bend between a first radius of curvature and a second radius of curvature, the first and second radius of curvature is from about 20 mm to about 10,000 mm, from about 20 mm to about 9,000 mm, from about 20 mm to about 8,000 mm, from about 20 mm to about 7,000 mm, from about 20 mm to about 6,000 mm, from about 20 mm to about 5,000 mm, from about 20 mm to about 4,000 mm, from about 20 mm to about 3,000 mm, from about 20 mm to about 2,000 mm, from about 20 mm to about 1,000 mm, from about 20 mm to about 750 mm, from about 20 mm to about 500 mm from about 20 mm to about 250 mm, from about 50 mm to about 10,000 mm, from about 75 mm to about 10,000 mm, from about 100 mm to about 10,000 mm, from about 200 mm to about 10,000 mm, from about 300 mm to about 10,000 mm, from about 400 mm to about 10,000 mm, from about 500 mm to about 10,000 mm, from about 600 mm to about 10,000 mm, from about 700 mm to about 10,000 mm, from about 800 mm to about 10,000 mm, from about 900 mm to about 10,000 mm, from about 1,000 mm to about 10,000 mm, from about 1,100 mm to about 10,000 mm, from about 1,200 mm to about 10,000 mm, from about 1,300 mm to about 10,000 mm, from about 1,400 mm to about 10,000 mm, from about 1,500 mm to about 10,000 mm, from about 1,600 mm to about 10,000 mm, from about 1,700 mm to about 10,000 mm, from about 1,800 mm to about 10,000 mm, from about 1,900 mm to about 10,000 mm, from about 2,000 mm to about 10,000 mm, from about 2,100 mm to about 10,000 mm, from about 2,200 mm to about 10,000 mm, from about 2,300 mm to about 10,000 mm, from about 2,400 mm to about 10,000 mm, from about 2,500 mm to about 10,000 mm, from about 3,000 mm to about 10,000 mm, from about 3,500 mm to about 10,000 mm, from about 4,000 mm to about 10,000 mm, from about 5,000 mm to about 10,000 mm, from about 7,500 mm to about 10,000 mm, from about 20 mm to about 1,000 mm, or from about 400 mm to about 10,000 mm.

In one or embodiments, the display disposed under the cover glass 25 may also be curved or flex and bend to exhibit the same or similar shapes described herein with respect to the cover glass 25. For example, the display may exhibit a radius of curvature as described herein with respect to the cover glass 25.

In one or more embodiments, the cover glass 25 has a thickness (t) that is about 1.5 mm or less. In one or embodiments, the cover glass 25 has a thickness (t) that is greater than about 0.125 mm (e.g., about 0.13 mm or greater, about 0.13 mm or greater, about 0.13 mm or greater, about 0.13 mm or greater, about 0.13 mm or greater, about 0.13 mm or greater, about 0.13 mm or greater, about 0.13 mm or greater, about 0.13 mm or greater, about 0.13 mm or greater, about 0.13 mm or greater, about 0.13 mm or greater, about 0.13 mm or greater, about 0.13 mm or greater, about 0.13 mm or greater, For example, the thickness may be in a range from about 0.01 mm to about 1.5 mm, 0.02 mm to about 1.5 mm, 0.03 mm to about 1.5 mm, 0.04 mm to about 1.5 mm, 0.05 mm to about 1.5 mm, 0.06 mm to about 1.5 mm, 0.07 mm to about 1.5 mm, 0.08 mm to about 1.5 mm, 0.09 mm to about 1.5 mm, 0.1 mm to about 1.5 mm, from about 0.15 mm to about 1.5 mm, from about 0.2 mm to about 1.5 mm, from about 0.25 mm to about 1.5 mm, from about 0.3 mm to about 1.5 mm, from about 0.35 mm to about 1.5 mm, from about 0.4 mm to about 1.5 mm, from about 0.45 mm to about 1.5 mm, from about 0.5 mm to about 1.5 mm, from about 0.55 mm to about 1.5 mm, from about 0.6 mm to about 1.5 mm, from about 0.65 mm to about 1.5 mm, from about 0.7 mm to about 1.5 mm, from about 0.01 mm to about 1.4 mm, from about 0.01 mm to about 1.3 mm, from about 0.01 mm to about 1.2 mm, from about 0.01 mm to about 1.1 mm, from about 0.01 mm to about 1.05 mm, from about 0.01 mm to about 1 mm, from about 0.01 mm to about 0.95 mm, from about 0.01 mm to about 0.9 mm, from about 0.01 mm to about 0.85 mm, from about 0.01 mm to about 0.8 mm, from about 0.01 mm to about 0.75 mm, from about 0.01 mm to about 0.7 mm, from about 0.01 mm to about 0.65 mm, from about 0.01 mm to about 0.6 mm, from about 0.01 mm to about 0.55 mm, from about 0.01 mm to about 0.5 mm, from about 0.01 mm to about 0.4 mm, from about 0.01 mm to about 0.3 mm, from about 0.01 mm to about 0.2 mm, from about 0.01 mm to about 0.1 mm, from about 0.04 mm to about 0.07 mm, from about 0.1 mm to about 1.4 mm, from about 0.1 mm to about 1.3 mm, from about 0.1 mm to about 1.2 mm, from about 0.1 mm to about 1.1 mm, from about 0.1 mm to about 1.05 mm, from about 0.1 mm to about 1 mm, from about 0.1 mm to about 0.95 mm, from about 0.1 mm to about 0.9 mm, from about 0.1 mm to about 0.85 mm, from about 0.1 mm to about 0.8 mm, from about 0.1 mm to about 0.75 mm, from about 0.1 mm to about 0.7 mm, from about 0.1 mm to about 0.65 mm, from about 0.1 mm to about 0.6 mm, from about 0.1 mm to about 0.55 mm, from about 0.1 mm to about 0.5 mm, from about 0.1 mm to about 0.4 mm, or from about 0.3 mm to about 0.7 mm.

In one or more embodiments, the thickness of the cover glass 25 is substantially uniform in that it the bend axis has substantially the same thickness as other portions of the cover glass 25. For example, the thickness of the cover glass 25 does not vary by more than ±10%, 5% or 2% across the total surface area of the first major surface, the second major surface or both the first and second major surfaces. In one or more embodiments, the thickness is substantially constant (within ±1% of the average thickness) across 90%, 95% or 99% of the total surface area of the first major surface, the second major surface or both the first and second major surfaces.

In one or more embodiments, the cover glass 25 has a width (W) in a range from about 5 cm to about 250 cm, from about 10 cm to about 250 cm, from about 15 cm to about 250 cm, from about 20 cm to about 250 cm, from about 25 cm to about 250 cm, from about 30 cm to about 250 cm, from about 35 cm to about 250 cm, from about 40 cm to about 250 cm, from about 45 cm to about 250 cm, from about 50 cm to about 250 cm, from about 55 cm to about 250 cm, from about 60 cm to about 250 cm, from about 65 cm to about 250 cm, from about 70 cm to about 250 cm, from about 75 cm to about 250 cm, from about 80 cm to about 250 cm, from about 85 cm to about 250 cm, from about 90 cm to about 250 cm, from about 95 cm to about 250 cm, from about 100 cm to about 250 cm, from about 110 cm to about 250 cm, from about 120 cm to about 250 cm, from about 130 cm to about 250 cm, from about 140 cm to about 250 cm, from about 150 cm to about 250 cm, from about 5 cm to about 240 cm, from about 5 cm to about 230 cm, from about 5 cm to about 220 cm, from about 5 cm to about 210 cm, from about 5 cm to about 200 cm, from about 5 cm to about 190 cm, from about 5 cm to about 180 cm, from about 5 cm to about 170 cm, from about 5 cm to about 160 cm, from about 5 cm to about 150 cm, from about 5 cm to about 140 cm, from about 5 cm to about 130 cm, from about 5 cm to about 120 cm, from about 5 cm to about 110 cm, from about 5 cm to about 110 cm, from about 5 cm to about 100 cm, from about 5 cm to about 90 cm, from about 5 cm to about 80 cm, or from about 5 cm to about 75 cm.

In one or more embodiments, the cover glass 25 has a length (L) in a range from about 5 cm to about 250 cm, from about 10 cm to about 250 cm, from about 15 cm to about 250 cm, from about 20 cm to about 250 cm, from about 25 cm to about 250 cm, from about 30 cm to about 250 cm, from about 35 cm to about 250 cm, from about 40 cm to about 250 cm, from about 45 cm to about 250 cm, from about 50 cm to about 250 cm, from about 55 cm to about 250 cm, from about 60 cm to about 250 cm, from about 65 cm to about 250 cm, from about 70 cm to about 250 cm, from about 75 cm to about 250 cm, from about 80 cm to about 250 cm, from about 85 cm to about 250 cm, from about 90 cm to about 250 cm, from about 95 cm to about 250 cm, from about 100 cm to about 250 cm, from about 110 cm to about 250 cm, from about 120 cm to about 250 cm, from about 130 cm to about 250 cm, from about 140 cm to about 250 cm, from about 150 cm to about 250 cm, from about 5 cm to about 240 cm, from about 5 cm to about 230 cm, from about 5 cm to about 220 cm, from about 5 cm to about 210 cm, from about 5 cm to about 200 cm, from about 5 cm to about 190 cm, from about 5 cm to about 180 cm, from about 5 cm to about 170 cm, from about 5 cm to about 160 cm, from about 5 cm to about 150 cm, from about 5 cm to about 140 cm, from about 5 cm to about 130 cm, from about 5 cm to about 120 cm, from about 5 cm to about 110 cm, from about 5 cm to about 110 cm, from about 5 cm to about 100 cm, from about 5 cm to about 90 cm, from about 5 cm to about 80 cm, or from about 5 cm to about 75 cm.

In one or more embodiments, the cover glass 25 includes a glass article or glass ceramic article that is strengthened. In one or more embodiments, the cover glass has a compressive stress (CS) region that extends from one or both major surfaces to a first depth of compression (DOC). The CS region includes a maximum CS magnitude (CSₘₐₓ). The glass article or glass ceramic has a CT region disposed in the central region that extends from the DOC to an opposing CS region. The CT region defines a maximum CT magnitude (CTmax). The CS region and the CT region define a stress profile that extends along the thickness of the glass article or glass ceramic.

In one or more embodiments, the glass article or glass ceramic article may be strengthened mechanically by utilizing a mismatch of the coefficient of thermal expansion between portions of the article to create a compressive stress region and a central region exhibiting a tensile stress. In some embodiments, the cover glass may be strengthened thermally by heating the glass to a temperature above the glass transition point and then rapidly quenching.

In one or more embodiments, the glass article or glass ceramic article may be chemically strengthening by ion exchange. In the ion exchange process, ions at or near the surface of the glass article or glass ceramic article are replaced by—or exchanged with—larger ions having the same valence or oxidation state. In those embodiments in which the glass article or glass ceramic article comprises an alkali aluminosilicate glass, ions in the surface layer of the article and the larger ions are monovalent alkali metal cations, such as Li+, Na+, K+, Rb+, and Cs+. Alternatively, monovalent cations in the surface layer may be replaced with monovalent cations other than alkali metal cations, such as Ag+ or the like. In such embodiments, the monovalent ions (or cations) exchanged into the glass article or glass ceramic article generate a stress.

Ion exchange processes are typically carried out by immersing a glass article or glass ceramic article in one or more molten salt baths containing the larger ions to be exchanged with the smaller ions in the glass article or glass ceramic article. It should be noted that aqueous salt baths may also be utilized. In addition, the composition of the bath(s) may include more than one type of larger ion (e.g., Na+ and K+) or a single larger ion. It will be appreciated by those skilled in the art that parameters for the ion exchange process, including but not limited to, bath composition and temperature, immersion time, the number of immersions of the glass article or glass ceramic article in a salt bath (or baths), use of multiple salt baths, additional steps such as annealing, washing, and the like, are generally determined by the composition of the glass article or glass ceramic article (including the structure of the article and any crystalline phases present) and the desired CS, DOC and CT values of the glass article or glass ceramic article that results from strengthening. Exemplary molten bath composition may include nitrates, sulfates, and chlorides of the larger alkali metal ion. Typical nitrates include KNO₃, NaNO₃, LiNO₃, NaSO₄ and combinations thereof. The temperature of the molten salt bath typically is in a range from about 380° C. up to about 450° C., while immersion times range from about 15 minutes up to about 100 hours depending on glass article or glass ceramic article thickness, bath temperature and glass (or monovalent ion) diffusivity. However, temperatures and immersion times different from those described above may also be used.

In one or more embodiments, the glass article or glass ceramic article may be immersed in a molten salt bath of 100% NaNO₃, 100% KNO₃, or a combination of NaNO₃ and KNO₃ having a temperature from about 370° C. to about 480° C. In some embodiments, the glass article or glass ceramic article may be immersed in a molten mixed salt bath including from about 1% to about 99% KNO₃ and from about 1% to about 99% NaNO₃. In one or more embodiments, the glass article or glass ceramic article may be immersed in a second bath, after immersion in a first bath. The first and second baths may have different compositions and/or temperatures from one another. The immersion times in the first and second baths may vary. For example, immersion in the first bath may be longer than the immersion in the second bath.

In one or more embodiments, the glass article or glass ceramic article may be immersed in a molten, mixed salt bath including NaNO₃ and KNO₃ (e.g., 49%/51%, 50%/50%, 51%/49%) having a temperature less than about 420° C. (e.g., about 400° C. or about 380° C.). for less than about 5 hours, or even about 4 hours or less. In one or more embodiments, the cover glass is immersed in a first mixed molten salt bath (e.g., 75% KNO₃/25% NaNO₃) having a temperature of 430° C. for 8 hours, and then immersed in a second pure molten salt bath of KNO₃ having a lower temperature than the first mixed molten salt bath for a shorter duration (e.g., about 4 hours). In one or more embodiments, the glass article or glass ceramic article may be chemically strengthened by immersing in a first bath having a composition of 75% KNO₃ and 25% NaNO₃ and bath temperature of 430° C. for 8 hours, followed by immersing in a second bath having a composition of 100% KNO₃ and bath temperature of 390° C. for 4 hours.

Ion exchange conditions can be tailored to provide a “spike” or to increase the slope of the stress profile at or near the surface of the resulting glass article or glass ceramic article. The spike may result in a greater surface CS value. This spike can be achieved by single bath or multiple baths, with the bath(s) having a single composition or mixed composition, due to the unique properties of the glass compositions used in the glass article or glass ceramic article described herein.

In one or more embodiments, where more than one monovalent ion is exchanged into the glass article or glass ceramic article, the different monovalent ions may exchange to different depths within the glass article or glass ceramic article (and generate different magnitudes stresses within the glass article or glass ceramic article at different depths). The resulting relative depths of the stress-generating ions can be determined and cause different characteristics of the stress profile.

In one or more embodiments, the glass article or glass ceramic article has a CSₘ that is about 900 MPa or greater, about 920 MPa or greater, about 940 MPa or greater, about 950 MPa or greater, about 960 MPa or greater, about 980 MPa or greater, about 1000 MPa or greater, about 1020 MPa or greater, about 1040 MPa or greater, about 1050 MPa or greater, about 1060 MPa or greater, about 1080 MPa or greater, about 1100 MPa or greater, about 1120 MPa or greater, about 1140 MPa or greater, about 1150 MPa or greater, about 1160 1 MPa or greater, about 1180 MPa or greater, about 1200 MPa or greater, about 1220 MPa or greater, about 1240 MPa or greater, about 1250 MPa or greater, about 1260 MPa or greater, about 1280 MPa or greater, or about 1300 MPa or greater. In one or more embodiments, the CSmax is in a range from about 900 MPa to about 1500 MPa, from about 920 MPa to about 1500 MPa, from about 940 MPa to about 1500 MPa, from about 950 MPa to about 1500 MPa, from about 960 MPa to about 1500 MPa, from about 980 MPa to about 1500 MPa, from about 1000 MPa to about 1500 MPa, from about 1020 MPa to about 1500 MPa, from about 1040 MPa to about 1500 MPa, from about 1050 MPa to about 1500 MPa, from about 1060 MPa to about 1500 MPa, from about 1080 MPa to about 1500 MPa, from about 1100 MPa to about 15001 MPa, from about 1120 MPa to about 1500 MPa, from about 1140 MPa to about 1500 MPa, from about 1150 MPa to about 15001 MPa, from about 1160 MPa to about 1500 MPa, from about 1180 MPa to about 1500 MPa, from about 1200 MPa to about 1500 MPa, from about 1220 MPa to about 1500 MPa, from about 1240 MPa to about 1500 MPa, from about 1250 MPa to about 1500 MPa, from about 1260 MPa to about 1500 MPa, from about 1280 MPa to about 1500 MPa, from about 1300 MPa to about 1500 MPa, from about 900 MPa to about 1480 MPa, from about 900 MPa to about 1460 MPa, from about 900 MPa to about 1450 MPa, from about 900 MPa to about 1440 MPa, from about 900 MPa to about 1420 MPa, from about 900 MPa to about 1400 MPa, from about 900 MPa to about 1380 MPa, from about 900 MPa to about 1360 MPa, from about 900 MPa to about 1350 MPa, from about 900 MPa to about 1340 MPa, from about 900 MPa to about 1320 MPa, from about 900 MPa to about 1300 MPa, from about 900 MPa to about 1280 MPa, from about 900 MPa to about 1260 MPa, from about 900 MPa to about 1250 MPa, from about 900 MPa to about 1240 MPa, from about 900 MPa to about 1220 MPa, from about 900 MPa to about 1210 MPa, from about 900 MPa to about 1200 MPa, from about 900 MPa to about 1180 MPa, from about 900 MPa to about 1160 MPa, from about 900 MPa to about 1150 MPa, from about 900 MPa to about 1140 MPa, from about 900 MPa to about 1120 MPa, from about 900 MPa to about 1100 MPa, from about 900 MPa to about 1080 MPa, from about 900 MPa to about 1060 MPa, from about 900 MPa to about 1050 MPa, or from about 950 MPa to about 1050 MPa, or from about 1000 MPa to about 1050 MPa. CSₘₐₓ may be measured at a major surface or may be found at a depth from the major surface within the CS region.

In one or more embodiments, the glass article or glass ceramic article has a stress profile with a CS magnitude of 800 MPa or greater at a depth within the glass article or glass ceramic article of about 10 micrometers from the first major surface 102 (CS₁₀). In one or more embodiments, the CS₁₀ is about 810 MPa or greater, about 820 MPa or greater, about 830 MPa or greater, about 840 MPa or greater, about 850 MPa or greater, about 860 MPa or greater, about 870 MPa or greater, about 880 MPa or greater, about 890 MPa or greater, or about 900 MPa or greater. In one or more embodiments, the CS₁₀ is in a range from about 800 MPa to about 1000 MPa, from about 825 MPa to about 1000 MPa, from about 850 MPa to about 1000 MPa, from about 875 MPa to about 1000 MPa, from about 900 MPa to about 1000 MPa, from about 925 MPa to about 1000 MPa, from about 950 MPa to about 1000 MPa, from about 800 MPa to about 975 MPa, from about 800 MPa to about 950 MPa, from about 800 MPa to about 925 MPa, from about 800 MPa to about 900 MPa, from about 800 MPa to about 875 MPa, or from about 800 MPa to about 850 MPa.

In one or more embodiments, the glass article or glass ceramic article has a stress profile with a CS magnitude of 700 MPa or greater, or about 750 MPa or greater at a depth within the glass article of about 5 micrometers from the first major surface 102 (CS₅). In one or more embodiments, the CS₅ is about 760 MPa or greater, about 770 MPa or greater, about 775 MPa or greater, about 780 MPa or greater, about 790 MPa or greater, about 800 MPa or greater, about 810 MPa or greater, about 820 MPa or greater, about 825 MPa or greater, or about 830 MPa or greater. In one or more embodiments, the CS₅ is in a range from about 700 MPa to about 900 MPa, from about 725 MPa to about 900 MPa, from about 750 MPa to about 900 MPa, from about 775 MPa to about 900 MPa, from about 800 MPa to about 900 MPa, from about 825 MPa to about 900 MPa, from about 850 MPa to about 900 MPa, from about 700 MPa to about 875 MPa, from about 700 MPa to about 850 MPa, from about 700 MPa to about 825 MPa, from about 700 MPa to about 800 MPa, from about 700 MPa to about 775 MPa, from about 750 to about 800 MPa, from about 750 MPa to about 850 MPa, or from about 700 MPa to about 750 MPa.

In one or more embodiments, the glass article or glass ceramic article has a stress profile with a CTₘₐₓ that is present or located at a depth within the glass article or glass ceramic article from the first major surface in a range from about 0.25 t to about 0.75 t. In one or more embodiments, CTₘₐₓ is present or located at a depth in a range from about 0.25 t to about 0.74 t, from about 0.25 t to about 0.72 t, from about 0.25 t to about 0.70 t, from about 0.25 t to about 0.68 t, from about 0.25 t to about 0.66 t, from about 0.25 t to about 0.65 t, from about 0.25 t to about 0.62 t, from about 0.25 t to about 0.60 t, from about 0.25 t to about 0.58 t, from about 0.25 t to about 0.56 t, from about 0.25 t to about 0.5 5 t, from about 0.25 t to about 0.54 t, from about 0.25 t to about 0.52 t, from about 0.25 t to about 0.5 t, from about 0.26 t to about 0.75 t, from about 0.28 t to about 0.75 t, from about 0.30 t to about 0.75 t, from about 0.3 2 t to about 0.75 t, from about 0.34 t to about 0.75 t, from about 0.3 5 t to about 0.75 t, from about 0.3 6 t to about 0.75 t, from about 0.38 t to about 0.75 t, from about 0.40 t to about 0.75 t, from about 0.42 t to about 0.75 t, from about 0.44 t to about 0.75 t, from about 0.45 t to about 0.75 t, from about 0.46 t to about 0.75 t, from about 0.48 t to about 0.50 t, from about 0.30 t to about 0.70 t, from about 0.3 5 t to about 0.65 t, from about 0.4 t to about 0.6 t, or from about 0.45 t to about 0.55 t. In one or more embodiments, the foregoing ranges for the location of CTmax is present when the glass article or glass ceramic article is in a substantially flat configuration (e.g., the cover glass has a radius of curvature of greater than about 5000 mm, or greater than about 10,000 mm).

In one or more embodiments, the CTₘₐₓ magnitude is about 80 MPa or less, about 78 MPa or less, about 76 MPa or less, about 75 MPa or less, about 74 MPa or less, about 72 MPa or less, about 70 MPa or less, about 68 MPa or less, about 66 MPa or less, about 65 MPa or less, about 64 MPa or less, about 62 MPa or less, about 60 MPa or less, about 58 MPa or less, about 56 MPa or less, about 55 MPa or less, about 54 MPa or less, about 52 MPa or less, or about 50 MPa or less. In one or more embodiments, the CTₘₐₓ magnitude is in a range from about 40 MPa to about 80 MPa, from about 45 MPa to about 80 MPa, from about 50 MPa to about 80 MPa, from about 55 MPa to about 80 MPa, from about 60 MPa to about 80 MPa, from about 65 MPa to about 80 MPa, from about 70 MPa to about 80 MPa, from about 401 MPa to about 75 MPa, from about 40 MPa to about 701 MPa, from about 40 MPa to about 65 MPa, from about 40 MPa to about 60 MPa, from about 40 MPa to about 55 MPa, or from about 40 MPa to about 50 MPa. In one or more embodiments, the foregoing ranges the magnitude of CTmax is present when the glass article or glass ceramic article is in a substantially flat configuration (e.g., the glass article or glass ceramic article has a radius of curvature of greater than about 5000 mm, or greater than about 10,000 mm).

In one or more embodiments, a portion of the stress profile has a parabolic-like shape. In some embodiments, the stress profile is free of a flat stress (i.e., compressive or tensile) portion or a portion that exhibits a substantially constant stress (i.e., compressive or tensile). In some embodiments, the CT region exhibits a stress profile that is substantially free of a flat stress or free of a substantially constant stress. In one or more embodiments, the stress profile is substantially free of any linear segments that extend in a depth direction or along at least a portion of the thickness t of the cover glass. In other words, the stress profile is substantially continuously increasing or decreasing along the thickness t. In some embodiments, the stress profile is substantially free of any linear segments in a depth direction having a length of about 10 micrometers or more, about 50 micrometers or more, or about 100 micrometers or more, or about 200 micrometers or more. As used herein, the term “linear” refers to a slope having a magnitude of less than about 51 MPa/micrometer, or less than about 2 MPa/micrometer along the linear segment. In some embodiments, one or more portions of the stress profile that are substantially free of any linear segments in a depth direction are present at depths within the cover glass of about 5 micrometers or greater (e.g., 10 micrometers or greater, or 15 micrometers or greater) from either one or both the first surface or the second surface. For example, along a depth of about 0 micrometers to less than about 5 micrometers from the first surface, the stress profile may include linear segments, but from a depth of about 5 micrometers or greater from the first surface, the stress profile may be substantially free of linear segments.

In one or more embodiments, all points of the CT region within 0.1 t, 0.15 t, 0.2 t, or 0.25 t from the depth of CTmax comprise a tangent having a non-zero slope. In one or more embodiments, all such points comprise a tangent having a slope that is greater than about 0.5 MPa/micrometer in magnitude, greater than about 0.75 MPa/micrometer in magnitude, greater than about 11 MPa/micrometer in magnitude, greater than about 1.51 MPa/micrometer in magnitude, or greater about 2 MPa/micrometer in magnitude than, or greater than about 0.5 MPa/micrometer in magnitude.

In one or more embodiments, all points of the stress profile at a depth from about 0.12 t or greater (e.g., from about 0.12 t to about 0.24 t, from about 0.14 t to about 0.24 t, from about 0.15 t to about 0.24 t, from about 0.16 t to about 0.24 t, from about 0.18 t to about 0.24 t, from about 0.12 t to about 0.22 t, from about 0.12 t to about 0.2 t, from about 0.12 t to about 0.18 t, from about 0.12 t to about 0.16 t, from about 0.12 t to about 0.15 t, from about 0.12 t to about 0.14 t, or from about 0.15 t to about 0.2 t) comprise a tangent having a non-zero slope.

In one or more embodiments, the glass article or glass ceramic article may be described in terms of the shape of the stress profile along at least a portion of the CT region (112 in FIG. 2). For example, in some embodiments, the stress profile along a substantial portion or the entire CT region may be approximated by equation. In some embodiments, the stress profile along the CT region may be approximated by equation (1):

Stress(x)=CT max−(((CT max·(n+1))/0.5ⁿ)·|(x/t)−0.5|ⁿ) (1)

In equation (1), the stress (x) is the stress value at position x. Here the stress is positive (tension). CTmax is the maximum central tension as a positive value in MPa. The value x is position along the thickness (t) in micrometers, with a range from 0 to t; x=0 is one surface (102, in FIG. 2), x=0.5 t is the center of the glass article or glass ceramic article, stress(x)=CTmax, and x=t is the opposite surface (104, in FIG. 2). CTmax used in equation (1) may be in the range from about 40 MPa to about 80 MPa, and n is a fitting parameter from 1.5 to 5 (e.g., 2 to 4, 2 to 3 or 1.8 to 2.2) whereby n=2 can provide a parabolic stress profile, exponents that deviate from n=2 provide stress profiles with near parabolic stress profiles.

In one or more embodiments, the DOC of the glass article or glass ceramic article is about 0.2 t or less. For example, DOC may be about 0.18 t or less, about 0.18 t or less, about 0.16 t or less, about 0.15 t or less, about 0.14 t or less, about 0.12 t or less, about 0.1 t or less, about 0.08 t or less, about 0.06 t or less, about 0.05 t or less, about 0.04 t or less, or about 0.03 t or less. In one or more embodiments, DOC is in a range from about 0.02 t to about 0.2 t, from about 0.04 t to about 0.2 t, from about 0.05 t to about 0.2 t, from about 0.06 t to about 0.2 t, from about 0.08 t to about 0.2 t, from about 0.1 t to about 0.2 t, from about 0.12 t to about 0.2 t, from about 0.14 t to about 0.2 t, from about 0.15 t to about 0.2 t, from about 0.16 t to about 0.2 t, from about 0.02 t to about 0.18 t, from about 0.02 t to about 0.16 t, from about 0.02 t to about 0.15 t, from about 0.02 t to about 0.14 t, from about 0.02 t to about 0.12 t, from about 0.02 t to about 0.1 t, from about 0.02 t to about 0.08, from about 0.02 t to about 0.06 t, from about 0.02 t to about 0.05 t, from about 0.1 t to about 0.8 t, from about 0.12 t to about 0.16 t, or from about 0.14 t to about 0.17 t.

In one or more embodiments, the glass article or glass ceramic article has a DOL that is in a range from about 10 micrometers to about 50 micrometers, from about 12 micrometers to about 50 micrometers, from about 14 micrometers to about 50 micrometers, from about 15 micrometers to about 50 micrometers, from about 16 micrometers to about 50 micrometers, from about 18 micrometers to about 50 micrometers, from about 20 micrometers to about 50 micrometers, from about 22 micrometers to about 50 micrometers, from about 24 micrometers to about 50 micrometers, from about 25 micrometers to about 50 micrometers, from about 26 micrometers to about 50 micrometers, from about 28 micrometers to about 50 micrometers, from about 30 micrometers to about 50 micrometers, from about 10 micrometers to about 48 micrometers, from about 10 micrometers to about 46 micrometers, from about 10 micrometers to about 45 micrometers, from about 10 micrometers to about 44 micrometers, from about 10 micrometers to about 42 micrometers, from about 10 micrometers to about 40 micrometers, from about 10 micrometers to about 38 micrometers, from about 10 micrometers to about 36 micrometers, from about 10 micrometers to about 35 micrometers, from about 10 micrometers to about 34 micrometers, from about 10 micrometers to about 32 micrometers, from about 10 micrometers to about 30 micrometers, from about 10 micrometers to about 28 micrometers, from about 10 micrometers to about 26 micrometers, from about 10 micrometers to about 25 micrometers, from about 20 micrometers to about 40 micrometers, from about 25 micrometers to about 40 micrometers, from about 20 micrometers to about 35 micrometers, or from about 25 micrometers to about 35 micrometers. In one or more embodiments, at least a portion of the stress profile comprises a spike region extending from the first major surface, a tail region and a knee region between the spike region and the tail region. The spike region 120 is within the CS region of the stress profile. In one or more embodiments, wherein all points of the stress profile in the spike region comprise a tangent having a slope in magnitude that is in a range from about 151 MPa/micrometer to about 2001 MPa/micrometer, from about 20 MPa/micrometer to about 2001 MPa/micrometer, from about 251 MPa/micrometer to about 200 MPa/micrometer, from about 301 MPa/micrometer to about 2001 MPa/micrometer, from about 35 MPa/micrometer to about 200 MPa/micrometer, from about 401 MPa/micrometer to about 200 MPa/micrometer, from about 45 MPa/micrometer to about 2001 MPa/micrometer, from about 1001 MPa/micrometer to about 200 MPa/micrometer, from about 1501 MPa/micrometer to about 200 MPa/micrometer, from about 15 MPa/micrometer to about 190 MPa/micrometer, from about 151 MPa/micrometer to about 1801 MPa/micrometer, from about 15 MPa/micrometer to about 170 MPa/micrometer, from about 15 MPa/micrometer to about 160 MPa/micrometer, from about 15 MPa/micrometer to about 1501 MPa/micrometer, from about 15 MPa/micrometer to about 1401 MPa/micrometer, from about 151 MPa/micrometer to about 1301 MPa/micrometer, from about 151 MPa/micrometer to about 1201 MPa/micrometer, from about 151 MPa/micrometer to about 1001 MPa/micrometer, from about 15 MPa/micrometer to about 750 MPa/micrometer, from about 15 MPa/micrometer to about 50 MPa/micrometer, from about 50 MPa/micrometer to about 1501 MPa/micrometer, or from about 75 MPa/micrometer to about 1251 MPa/micrometer.

In one or more embodiments, and all points in the tail region comprise a tangent having a slope in magnitude that is in a range from about 0.011 MPa/micrometer to about 3 MPa/micrometer, from about 0.051 MPa/micrometer to about 31 MPa/micrometer, from about 0.1 MPa/micrometer to about 3 MPa/micrometer, from about 0.251 MPa/micrometer to about 3 MPa/micrometer, from about 0.51 MPa/micrometer to about 31 MPa/micrometer, from about 0.75 MPa/micrometer to about 31 MPa/micrometer, from about 1 MPa/micrometer to about 3 MPa/micrometer, from about 1.251 MPa/micrometer to about 31 MPa/micrometer, from about 1.5 MPa/micrometer to about 3 MPa/micrometer, from about 1.751 MPa/micrometer to about 3 MPa/micrometer, from about 21 MPa/micrometer to about 31 MPa/micrometer, from about 0.01 MPa/micrometer to about 2.91 MPa/micrometer, from about 0.011 MPa/micrometer to about 2.8 MPa/micrometer, from about 0.01 MPa/micrometer to about 2.751 MPa/micrometer, from about 0.011 MPa/micrometer to about 2.71 MPa/micrometer, from about 0.01 MPa/micrometer to about 2.61 MPa/micrometer, from about 0.011 MPa/micrometer to about 2.5 MPa/micrometer, from about 0.011 MPa/micrometer to about 2.41 MPa/micrometer, from about 0.011 MPa/micrometer to about 2.21 MPa/micrometer, from about 0.011 MPa/micrometer to about 2.11 MPa/micrometer, from about 0.011 MPa/micrometer to about 21 MPa/micrometer, from about 0.011 MPa/micrometer to about 1.751 MPa/micrometer, from about 0.01 MPa/micrometer to about 1.51 MPa/micrometer, from about 0.011 MPa/micrometer to about 1.25 MPa/micrometer, from about 0.01 MPa/micrometer to about 11 MPa/micrometer, from about 0.011 MPa/micrometer to about 0.751 MPa/micrometer, from about 0.01 MPa/micrometer to about 0.51 MPa/micrometer, from about 0.011 MPa/micrometer to about 0.25 MPa/micrometer, from about 0.11 MPa/micrometer to about 21 MPa/micrometer, from about 0.51 MPa/micrometer to about 21 MPa/micrometer, or from about 1 MPa/micrometer to about 31 MPa/micrometer.

In one or more embodiments, the CS magnitude within the spike region is in a range from about greater than 200 MPa to about 1500 MPa. For example, the CS magnitude in the spike region may be in a range from about 250 MPa to about 1500 MPa, from about 300 MPa to about 1500 MPa, from about 3501 MPa to about 1500 MPa, from about 400 MPa to about 1500 MPa, from about 450 MPa to about 1500 MPa, from about 500 MPa to about 1500 MPa, from about 550 MPa to about 1500 MPa, from about 600 MPa to about 1500 MPa, from about 750 MPa to about 1500 MPa, from about 800 MPa to about 1500 MPa, from about 850 MPa to about 1500 MPa, from about 900 MPa to about 1500 MPa, from about 950 MPa to about 1500 MPa, from about 1000 MPa to about 1500 MPa, from about 1050 MPa to about 1500 MPa, from about 1100 MPa to about 15001 MPa, from about 1200 MPa to about 1500 MPa, from about 250 MPa to about 1450 MPa, from about 250 MPa to about 1400 MPa, from about 2501 MPa to about 1350 MPa, from about 2501 MPa to about 13001 MPa, from about 250 MPa to about 1250 MPa, from about 250 MPa to about 1200 MPa, from about 2501 MPa to about 1150 MPa, from about 2501 MPa to about 1100 MPa, from about 250 MPa to about 1050 MPa, from about 2501 MPa to about 1000 MPa, from about 2501 MPa to about 950 MPa, from about 2501 MPa to about 90 MPa, from about 2501 MPa to about 850 MPa, from about 250 MPa to about 800 MPa, from about 250 MPa to about 750 MPa, from about 250 MPa to about 7001 MPa, from about 2501 MPa to about 650 MPa, from about 250 MPa to about 600 MPa, from about 250 MPa to about 550 MPa, from about 250 MPa to about 500 MPa, from about 800 MPa to about 1400 MPa, from about 900 MPa to about 1300 MPa, from about 900 MPa to about 1200 MPa, from about 900 MPa to about 1100 MPa, or from about 900 MPa to about 1050 MPa.

In one or more embodiments, the CS magnitude in the knee region is in a range from about 51 MPa to about 200 MPa, from about 10 MPa to about 200 MPa, from about 15 MPa to about 200 MPa, from about 20 MPa to about 200 MPa, from about 25 MPa to about 200 MPa, from about 301 MPa to about 200 MPa, from about 351 MPa to about 200 MPa, from about 40 MPa to about 200 MPa, from about 45 MPa to about 200 MPa, from about 50 MPa to about 200 MPa, from about 551 MPa to about 200 MPa, from about 60 MPa to about 200 MPa, from about 65 MPa to about 200 MPa, from about 75 MPa to about 200 MPa, from about 80 MPa to about 200 MPa, from about 90 MPa to about 200 MPa, from about 100 MPa to about 200 MPa, from about 125 MPa to about 200 MPa, from about 150 MPa to about 200 MPa, from about 5 MPa to about 190 MPa, from about 51 MPa to about 180 MPa, from about 5 MPa to about 175 MPa, from about 5 MPa to about 170 MPa, from about 5 MPa to about 160 MPa, from about 51 MPa to about 150 MPa, from about 5 MPa to about 140 MPa, from about 51 MPa to about 1301 MPa, from about 51 MPa to about 1251 MPa, from about 5 MPa to about 120 MPa, from about 51 MPa to about 110 MPa, from about 51 MPa to about 100 MPa, from about 5 MPa to about 75 MPa, from about 5 MPa to about 50 MPa, from about 5 MPa to about 25 MPa, or from about 10 MPa to about 100 MPa.

In one or more embodiments, the knee region of the stress profile extends from about 10 micrometers to about 50 micrometers from the first major surface. For example, the knee region of the stress profile extends from about 12 micrometers to about 50 micrometers, from about 14 micrometers to about 50 micrometers, from about 15 micrometers to about 50 micrometers, from about 16 micrometers to about 50 micrometers, from about 18 micrometers to about 50 micrometers, from about 20 micrometers to about 50 micrometers, from about 22 micrometers to about 50 micrometers, from about 24 micrometers to about 50 micrometers, from about 25 micrometers to about 50 micrometers, from about 26 micrometers to about 50 micrometers, from about 28 micrometers to about 50 micrometers, from about 30 micrometers to about 50 micrometers, from about 32 micrometers to about 50 micrometers, from about 34 micrometers to about 50 micrometers, from about 35 micrometers to about 50 micrometers, from about 36 micrometers to about 50 micrometers, from about 38 micrometers to about 50 micrometers, from about 40 micrometers to about 50 micrometers, from about 10 micrometers to about 48 micrometers, from about 10 micrometers to about 46 micrometers, from about 10 micrometers to about 45 micrometers, from about 10 micrometers to about 44 micrometers, from about 10 micrometers to about 42 micrometers, from about 10 micrometers to about 40 micrometers, from about 10 micrometers to about 38 micrometers, from about 10 micrometers to about 36 micrometers, from about 10 micrometers to about 35 micrometers, from about 10 micrometers to about 34 micrometers, from about 10 micrometers to about 32 micrometers, from about 10 micrometers to about 30 micrometers, from about 10 micrometers to about 28 micrometers, from about 10 micrometers to about 26 micrometers, from about 10 micrometers to about 25 micrometers, from about 10 micrometers to about 24 micrometers, from about 10 micrometers to about 22 micrometers, or from about 10 micrometers to about 20 micrometers, from the first major surface.

In one or more embodiments, the tail region extends from about the knee region to the depth of CTₘₐₓ. In one or more embodiments, the tail region comprises one or both of a compressive stress tail region, and a tensile stress tail region.

In one or more embodiments, the either one of or both the first major surface and the second major surface of the cover glass 25 includes a surface treatment. The surface treatment may cover at least a portion of the first major surface and the second major surface. Exemplary surface treatments include an easy-to-clean surface, an anti-glare surface, an anti-reflective surface, a haptic surface, and a decorative surface. In one or more embodiments, the at least a portion of the first major surface and/or the second major surface may include any one, any two or all three of an anti-glare surface, an anti-reflective surface, a haptic surface, and a decorative surface. For example, first major surface may include an anti-glare surface and the second major surface may include an anti-reflective surface. In another example, the first major surface includes an anti-reflective surface and the second major includes an anti-glare surface. In yet another example, the first major surface comprises either one of or both the anti-glare surface and the anti-reflective surface, and the second major surface includes the decorative surface.

The anti-glare surface may be formed using an etching process and may exhibit a transmission haze 20% or less (e.g., about 15% or less, about 10% or less, 5% or less). In one or more the anti-glare surface may have a distinctiveness of image (DOI) of about 80 or less. As used herein, the terms “transmission haze” and “haze” refer to the percentage of transmitted light scattered outside an angular cone of about ±2.5° in accordance with ASTM procedure D1003. For an optically smooth surface, transmission haze is generally near zero. As used herein, the term “distinctness of image” is defined by method A of ASTM procedure D5767 (ASTM 5767), entitled “Standard Test Methods for Instrumental Measurements of Distinctness-of-Image Gloss of Coating Surfaces.” In accordance with method A of ASTM 5767, substrate reflectance factor measurements are made on the anti-glare surface at the specular viewing angle and at an angle slightly off the specular viewing angle. The values obtained from these measurements are combined to provide a DOI value. In particular, DOI is calculated according to the equation (2)

$$DOI = [ 1 - \frac{Ros}{Rs} ] \times 100 , \qquad ( 2 )$$

where Ros is the relative reflection intensity average between 0.2° and 0.4 away from the specular reflection direction, and Rs is the relative reflection intensity average in the specular direction (between +0.05° and −0.05°, centered around the specular reflection direction). If the input light source angle is +20° from the sample surface normal (as it is throughout this disclosure), and the surface normal to the sample is taken as 0°, then the measurement of specular reflected light Rs is taken as an average in the range of about −19.95° to −20.05°, and Ros is taken as the average reflected intensity in the range of about −20.2° to −20.4° (or from −19.6° to −19.8°, or an average of both of these two ranges). As used herein, DOI values should be directly interpreted as specifying a target ratio of Ros/Rs as defined herein. In some embodiments, the anti-glare surface has a reflected scattering profile such that >95% of the reflected optical power is contained within a cone of +1-10°, where the cone is centered around the specular reflection direction for any input angle.

The anti-glare surface may have a surface roughness (Ra) from about 10 nm to about 70 nm (e.g., from about 10 nm to about 68 nm, from about 10 nm to about 66 nm, from about 10 nm to about 65 nm, from about 10 nm to about 64 nm, from about 10 nm to about 62 nm, from about 10 nm to about 60 nm, from about 10 nm to about 55 nm, from about 10 nm to about 50 nm, from about 10 nm to about 45 nm, from about 10 nm to about 40 nm, from about 12 nm to about 70 nm, from about 14 nm to about 70 nm, from about 15 nm to about 70 nm, from about 16 nm to about 70 nm, from about 18 nm to about 70 nm, from about 20 nm to about 70 nm, from about 22 nm to about 70 nm, from about 24 nm to about 70 nm, from about 25 nm to about 70 nm, from about 26 nm to about 70 nm, from about 28 nm to about 70 nm, or from about 30 nm to about 70 nm. The anti-glare surface may include a textured surface with plurality of concave features having an opening facing outwardly from the surface. The opening may have an average cross-sectional dimension of about 30 micrometers or less (e.g., from about 2 micrometers to about 30 micrometers, from about 4 micrometers to about 30 micrometers, from about 5 micrometers to about 30 micrometers, from about 6 micrometers to about 30 micrometers, from about 8 micrometers to about 30 micrometers, from about 10 micrometers to about 30 micrometers, from about 12 micrometers to about 30 micrometers, from about 15 micrometers to about 30 micrometers, from about 2 micrometers to about 25 micrometers, from about 2 micrometers to about 20 micrometers, from about 2 micrometers to about 18 micrometers, from about 2 micrometers to about 16 micrometers, from about 2 micrometers to about 15 micrometers, from about 2 micrometers to about 14 micrometers, from about 2 micrometers to about 12 micrometers, or from about 8 micrometers to about 15 micrometers. In one or more embodiments, the anti-glare surface exhibits low sparkle (in terms of low pixel power deviation reference or PPDr) such as PPDr of about 6% or less, 4% or less, 3% or less, 2% or less, or about 1% or less. As used herein, the terms “pixel power deviation referenced” and “PPDr” refer to the quantitative measurement for display sparkle. Unless otherwise specified, PPDr is measured using a display arrangement that includes an edge-lit liquid crystal display screen (twisted nematic liquid crystal display) having a native sub-pixel pitch of 60 μm×180 μm and a sub-pixel opening window size of about 44 μm x about 142 The front surface of the liquid crystal display screen had a glossy, anti-reflection type linear polarizer film. To determine PPDr of a display system or an anti-glare surface that forms a portion of a display system, a screen is placed in the focal region of an “eye-simulator” camera, which approximates the parameters of the eye of a human observer. As such, the camera system includes an aperture (or “pupil aperture”) that is inserted into the optical path to adjust the collection angle of light, and thus approximate the aperture of the pupil of the human eye. In the PPDr measurements described herein, the iris diaphragm subtends an angle of 18 milliradians.

The anti-reflective surface may be formed by a multi-layer coating stack formed from alternating layers of a high refractive index material and a low refractive index material. Such coatings stacks may include 6 layers or more. In one or more embodiment, the anti-reflective surface may exhibit a single-side average light reflectance of about 2% or less (e.g., about 1.5% or less, about 1% or less, about 0.75% or less, about 0.5% or less, or about 0.25% or less) over the optical wavelength regime in the range from about 400 nm to about 800 nm. The average reflectance is measured at an incident illumination angle greater than about 0 degrees to less than about 10 degrees.

The decorative surface may include any aesthetic design formed from a pigment (e.g., ink, paint and the like) and can include a wood-grain design, a brushed metal design, a graphic design, a portrait, or a logo. In one or more embodiments, the decorative surface exhibits a deadfront effect in which the decorative surface disguises or masks the underlying display from a viewer when the display is turned off but permits the display to be viewed when the display is turned on. The decorative surface may be printed onto the glass substrate. In one or more embodiments, the anti-glare surface includes an etched surface. In one or more embodiments, the anti-reflective surface includes a multi-layer coating. In one or more embodiments, the easy-to-clean surface includes an oleophobic coating that imparts anti-fingerprint properties. In one or more embodiments, the haptic surface includes a raised or recessed surface formed from depositing a polymer or glass material on the surface to provide a user with tactile feedback when touched.

In one or more embodiments, the surface treatment (i.e., the easy-to-clean surface, the anti-glare surface, the anti-reflective surface, the haptic surface and/or the decorative surface) is disposed on at least a portion of the periphery of the first and/or second major surface and the interior portion of such surface is substantially free of the surface treatment.

Aspect (1) of this disclosure pertains to a system comprising: a processor capable of executing instructions; and a non-transitory, machine readable storage medium encoded with program instructions for providing a stiffness design guideline for a support structure for a flexible display for mounting on a dashboard of an automobile to meet the requirement of a head form impact test, such that when said processor executes the program instructions, the processor performs a method comprising:

(a1) determining linear spring stiffness K1 of the support structure; and

(a2) determining the allowable rotational spring stiffness K2 of the support structure by using the following: K2≤0.3414×(K1)²−1753.3×(K1)+3E6; or

(b1) determining rotational spring stiffness K2 of the support structure; and

(b2) determining the allowable linear spring stiffness K1 of the support structure by using the following: K1≤(2E−10)×(K2)²−0.0014×(K2)+2822.9.

Aspect (1) of this disclosure pertains to a non-transitory, machine readable storage medium encoded with program instructions for providing a stiffness design guideline for a support structure for a flexible display for mounting on a dashboard of an automobile to meet the requirement of a head form impact test, such that when a processor executes the program instructions, the processor performs a method comprising: determining linear spring stiffness K1 of the support structure; and determining the allowable rotational spring stiffness K2 of the support structure by using the following: K2≤0.3414× (K1)²−1753.3× (K1)+3E6; or determining rotational spring stiffness K2 of the support structure; and determining the allowable linear spring stiffness K1 of the support structure by using the following: K1≤1500 N/mm.

Aspect (3) of this disclosure pertains to a method for providing a stiffness design guideline for a support structure for a flexible display for mounting on a dashboard of an automobile to meet the requirement of a head form impact test (HIT) that impacts the flexible display with a head form mass of 6.8 kg traveling at 6.67 m/s, the method comprising: determining linear spring stiffness K1 of the support structure; and determining the allowable rotational spring stiffness K2 of the support structure by using the following: K2≤0.3414× (K1)²−1753.3× (K1)+3E6; or determining rotational spring stiffness K2 of the support structure; and determining the allowable linear spring stiffness K1 of the support structure by using the following: K1≤(2E−10)× (K2)²−0.0014× (K2)+2822.9.

Aspect (4) of this disclosure pertains to a display panel having a front side and a backside, the display panel comprising: a cover glass on the front side; a back plate on the backside; a living hinge portion, wherein the cover glass and the back plate in the living hinge portion are flexible; and a strap spanning across the living hinge portion and attached to the back plate on both sides of the living hinge portion, wherein the strap is stiffer than the living hinge portion of the flexible display panel such that the strap provides a predetermined amount of resistance to the living hinge portion from bending.

Aspect (5) of this disclosure pertains to the display of Aspect (4), wherein the strap is attached to the back plate on one side of the living hinge portion so that there is no relative movement between the strap and the back plate, and the strap is attached to the other side of the living hinge portion in a manner that allows some lateral sliding movement between the strap and the back plate.

Aspect (6) of this disclosure pertains to the display of Aspect (4) or Aspect (5), wherein the predetermined amount of resistance to bending provided by the strap is sufficient to limit the bending of the living hinge portion to a predetermined amount when an impact force that is equivalent to a head form impact test is exerted on the living hinge portion from the front side.

Aspect (7) of this disclosure pertains to the display of Aspect (6), wherein the impact force is equivalent to an impact force exerted by an 6.8 kg head form traveling at 6.67 meters/second on the living hinge portion.

Aspect (8) of this disclosure pertains to the display of Aspect (7), wherein the predetermined amount of resistance to bending provided by the strap is sufficient to limit the bending of the living hinge portion so that the 6.8 kg head form traveling at 6.67 meters/second impacting the living hinge portion would decelerate at a rate not more than 80 g over a 3 ms period, wherein g is the gravitational acceleration.

Aspect (9) of this disclosure pertains to a display panel having a front side and a backside, the display panel comprising: a first portion; a second portion; a living hinge portion connecting the first portion and the second portion, wherein the first portion is affixed to a fixed structure and the second portion is movable with respect to the first portion by operation of the living hinge; and an actuating rod hingeably attached to the backside of the second portion for actuating the movement of the second portion with respect to the first portion, wherein the actuating rod comprises a damper assembly that is configured for providing a predetermined amount of resistance to the second portion from being forced backward by an impact force applied from the front side.

Aspect (10) of this disclosure pertains to the display panel of Aspect (9), wherein the predetermined amount of resistance provided by the damper assembly is sufficient to dampen the impact force that is equivalent to an impact force exerted by an 6.8 kg head form traveling at 6.67 meters/second on the second portion of the display panel from the front side such that the head form would decelerate at a rate not more than 80 g over a 3 ms period, wherein g is the gravitational acceleration.

Aspect (11) of this disclosure pertains to the display panel of Aspect (9) or Aspect (10), further comprising a cover glass on the front side.

Aspect (12) of this disclosure pertains to the display panel of any one of Aspects (9) through (11), further comprising a back plate on the backside and the actuating rod is hingeably attached to the back plate.

Aspect (13) of this disclosure pertains to a display panel having a front side and a backside, the display panel comprising: a cover glass on the front side; a back plate on the backside; a living hinge portion, wherein the cover glass and the back plate in the living hinge portion are flexible; and a shock absorber in proximity to the backside of the living hinge portion and mounted to a fixed structure, wherein the shock absorber provides a predetermined amount of resistance to the living hinge portion from being forced backward by an impact force applied from the front side.

Aspect (14) of this disclosure pertains to the display panel of Aspect (13), wherein the impact force is equivalent to an impact force exerted by an 6.8 kg head form traveling at 6.67 meters/second on the living hinge portion.

Aspect (15) of this disclosure pertains to the display panel of Aspect (13) or Aspect (14), wherein the predetermined amount of resistance provided by the shock absorber is sufficient to limit the deceleration of the 6.8 kg head form impacting the living hinge portion would decelerate at a rate not more than 80 g over a 3 ms period, wherein g is the gravitational acceleration.

Aspect (16) of this disclosure pertains to the display panel of any one of Aspects (13) through (15), wherein the display panel is a display panel in an automobile that is equipped with an air bag system that deploys when the automobile is in a collision and the shock absorber is an air bag that is synchronized to be deployed at the same time as the air bag system.

Aspect (17) of this disclosure pertains to a display panel having a front side and a backside, the display panel comprising: a first portion; a second portion; a living hinge portion connecting the first portion and the second portion, wherein the first portion is affixed to a fixed structure and the second portion is movable with respect to the first portion by operation of the living hinge; and an actuating rod attached to the backside of the second portion by a hinged joint for actuating the movement of the second portion with respect to the first portion by a flexion of the living hinge portion, wherein the hinged joint is configured to provide a predetermined amount of resistance to the second portion from being forced backward by an impact force applied from the front side somewhere between the hinged joint and the first portion by resisting rotation of the second portion about the hinged joint.

Aspect (18) of this disclosure pertains to the display panel of Aspect (17), wherein the predetermined amount of resistance provided by the hinged joint is sufficient to dampen the impact force that is equivalent to an impact force exerted by an 6.8 kg head form traveling at 6.67 meters/second on the second portion of the display panel from the front side such that the head form would decelerate at a rate not more than 80 g over a 3 ms period, wherein g is the gravitational acceleration.

Aspect (19) of this disclosure pertains to the display panel of Aspect (17) or Aspect (18), wherein the hinged joint comprises a gear assembly configured to provide said predetermined amount of resistance.

Aspect (20) of this disclosure pertains to the display panel of any one of Aspects (17) through (19), further comprising a support foot provided on the actuating rod and extending toward and contacting the backside at a point between the hinged joint and the living hinge portion, wherein the support foot braces against the second portion of the display panel and prevents the second portion from rotating about the hinged joint more than a predetermined amount when said impact force is applied.

Aspect (21) of this disclosure pertains to the display panel of any one of Aspects (17) through (20), wherein the hinged joint comprises a locking hinge pin that locks the hinged joint and provides the predetermined amount of resistance that is sufficient to prevent the second portion from being rotated about the hinged joint beyond a predetermined amount when said impact force is applied.

Aspect (22) of this disclosure pertains to the display panel of Aspect (21), wherein the locking hinge pin comprises a keyed head portion, wherein the locking hinge pin is configured to be movable along the hinge axis between an unlocked position and a locked position, wherein when the applied impact force causes the second portion of the display panel to rotate about the hinged joint more than a predetermined amount, the hinge pin moves into its locked position preventing the second portion from rotating any further.

Aspect (23) of this disclosure pertains to a display panel having a front side and a backside, the display panel comprising: a cover glass on the front side; a back plate on the backside; an adhesive layer between the cover glass and the back plate; and a living hinge portion, wherein the cover glass, the adhesive layer, and the back plate in the living hinge portion are flexible; wherein the adhesive layer has a thickness and the adhesive layer in the living hinge portion comprise a plurality of perforations extending through the thickness of the adhesive layer, whereby the perforations in the adhesive layer allows the portion of the cover glass in the living hinge portion to travel further.

Aspect (24) of this disclosure pertains to the display panel of Aspect (23), wherein each of the perforations are 10 μm to 50 mm apart from its nearest neighboring perforation.

Aspect (25) of this disclosure pertains to the display panel of Aspect (23) or Aspect (24), wherein each of the perforations has a cylindrical shape having a diameter that is 5 μm to 10 mm.

Aspect (26) of this disclosure pertains to the display panel of any one of Aspects (23) through (25), wherein the perforations are oriented at an angle that is 70° to 120° with respect to the back plate.

Aspect (27) of this disclosure pertains to the display panel of Aspect (26), wherein all of the perforations are oriented in the same directions.

Aspect (28) of this disclosure pertains to the display panel of Aspect (26), wherein all of the perforations are oriented in random orientation.

Aspect (29) of this disclosure pertains to the display panel of any one of Aspects (23) through (28), wherein an axis of bending is defined within the living hinge portion and the perforations are oriented at an angle that is 70° to 120° with respect to the back plate and some of the plurality of perforations are oriented toward the axis of bending.

Aspect (30) of this disclosure pertains to a display panel having a front side and a backside, the display panel comprising: a first portion; a second portion; a living hinge portion connecting the first portion and the second portion, wherein the first portion is affixed to a fixed structure and the second portion is movable with respect to the first portion by operation of the living hinge; an actuating rod attached to the backside of the second portion by a hinged joint for actuating the movement of the second portion with respect to the first portion by a flexion of the living hinge portion; and a supporting rod connecting the actuating rod to a point on the backside of the second portion between the hinged joint and the living hinge portion; wherein the supporting rod acts as a brace against the second portion from being forced backward by an impact force applied from the front side somewhere between the hinged joint and the first portion.

Those skilled in the art will appreciate that many modifications to the exemplary embodiments described herein are possible without departing from the spirit and scope of the disclosure. Thus, the description is not intended and should not be construed to be limited to the examples given but should be granted the full breadth of protection afforded by the appended claims and equivalents thereto. In addition, it is possible to use some of the features of the present disclosure without the corresponding use of other features. Accordingly, the foregoing description of exemplary or illustrative embodiments is provided for the purpose of illustrating the principles of the present disclosure and not in limitation thereof and can include modification thereto and permutations thereof.

While preferred embodiments of the present disclosure have been described, it is to be understood that the embodiments described are illustrative only and that the scope of the invention is to be defined solely by the appended claims when accorded a full range of equivalence, many variations and modifications naturally occurring to those of skill in the art from a perusal hereof.

What is claimed is:

1. (canceled)

2. (canceled)

3. (canceled)

4. A display panel having a front side and a backside, the display panel comprising:
a cover glass on the front side;
a support structure on the backside; and
a living hinge portion, wherein the cover glass and the support structure in the living hinge portion are flexible, wherein:
the support structure supports the cover glass such that, when a headform having a mass of 6.8 mm strikes the front side of the living hinge portion at a velocity of 6.67 m/s, a deceleration of the headform does not exceed 80 g, where g is gravitational acceleration, and
the support structure comprises one of:
a strap spanning across the living hinge portion and attached to the back plate on both sides of the living hinge portion, wherein the strap is stiffer than the living hinge portion of the flexible display panel such that the strap provides a predetermined amount of resistance to the living hinge portion from bending,
an actuating rod hingeably attached to the backside of a second portion of the display panel for actuating the movement of the second portion with respect to a first portion of the display panel, wherein the first portion and the second portion are connected to one another via the live hinge portion, or
a shock absorber in proximity to the backside of the living hinge portion and mounted to a fixed structure, wherein the shock absorber provides a predetermined amount of resistance to the living hinge portion from being forced backward by the headform.

5. The display panel of claim 4, wherein the support structure comprises the strap and the strap is attached to the back plate on one side of the living hinge portion so that there is no relative movement between the strap and the back plate, and the strap is attached to the other side of the living hinge portion in a manner that allows some lateral sliding movement between the strap and the back plate.

6. (canceled)

7. (canceled)

8. (canceled)

9. The display panel of claim 4, wherein the support structure comprises the actuating rod hingeably attached to the backside of the second portion of the display panel,
wherein the actuating rod comprises a damper assembly that is configured for providing a predetermined amount of resistance to the second portion from being forced backward by the headform.

10. (canceled)

11. (canceled)

12. The display panel of claim 9, further comprising a back plate on the backside, wherein the actuating rod is hingeably attached to the back plate.

13. The display panel of claim 4, wherein the support structure comprises the
shock absorber in proximity to the backside of the living hinge portion and mounted to the fixed structure.

14. (canceled)

15. (canceled)

16. The display panel of claim 13, wherein the display panel is a display panel in an automobile that is equipped with an air bag system that deploys when the automobile is in a collision and the shock absorber is an air bag that is synchronized to be deployed at the same time as the air bag system.

17. The display panel of claim 4, wherein the support structure comprises the actuating rod hingeably attached to the backside of the second portion of the display panel, wherein the
actuating rod is attached to the backside of the second portion by a hinged joint for actuating the movement of the second portion with respect to the first portion by a flexion of the living hinge portion,
wherein the hinged joint is configured to provide a predetermined amount of resistance to the second portion from being forced backward by the headform by resisting rotation of the second portion about the hinged joint.

18. (canceled)

19. The display panel of claim 17, wherein the hinged joint comprises a gear assembly configured to provide said predetermined amount of resistance.

20. The display panel of claim 17, further comprising a support foot provided on the actuating rod and extending toward and contacting the backside at a point between the hinged joint and the living hinge portion, wherein the support foot braces against the second portion of the display panel and prevents the second portion from rotating about the hinged joint more than a predetermined amount when said impact force is applied.

21. The display panel of claim 17, wherein the hinged joint comprises a locking hinge pin that locks the hinged joint and provides the predetermined amount of resistance that is sufficient to prevent the second portion from being rotated ab out the hinged joint beyond a predetermined amount when struck by the headform.

22. The display panel of claim 21, wherein the locking hinge pin comprises a keyed head portion,
wherein the locking hinge pin is configured to be movable along the hinge axis between an unlocked position and a locked position,
wherein when the headform causes the second portion of the display panel to rotate about the hinged joint more than a predetermined amount, the hinge pin moves into its locked position preventing the second portion from rotating any further.

23. A display panel having a front side and a backside, the display panel comprising:
a cover glass on the front side;
a back plate on the backside;
an adhesive layer between the cover glass and the back plate; and
a living hinge portion, wherein the cover glass, the adhesive layer, and the back plate in the living hinge portion are flexible;
wherein the back plate and adhesive support the cover glass such that, when a headform having a mass of 6.8 mm strikes the front side of the living hinge portion at a velocity of 6.67 m/s, a deceleration of the headform does not exceed 80 g, where g is gravitational acceleration, and
wherein the adhesive layer has a thickness and the adhesive layer in the living hinge portion comprise a plurality of perforations extending through the thickness of the adhesive layer, whereby the perforations in the adhesive layer allows the portion of the cover glass in the living hinge portion to travel further as a result of being struck by the headform.

24. The display panel of claim 23, wherein each of the perforations are 10 μm to 50 mm apart from its nearest neighboring perforation.

25. The display panel of claim 24, wherein each of the perforations has a cylindrical shape having a diameter that is 5 μm to 10 mm.

26. The display panel of claim 23, wherein the perforations are oriented at an angle that is 70° to 120° with respect to the back plate.

27. The display panel of claim 26, wherein all of the perforations are oriented in the same direction.

28. The display panel of claim 26, wherein all of the perforations are oriented in random orientations.

29. The display panel of claim 23, wherein an axis of bending is defined within the living hinge portion and the perforations are oriented at an angle that is 70° to 120° with respect to the back plate and some of the plurality of perforations are oriented toward the axis of bending.

30. A display panel having a front side and a backside, the display panel comprising:
a first portion;
a second portion;
a living hinge portion connecting the first portion and the second portion, wherein the first portion is affixed to a fixed structure and the second portion is movable with respect to the first portion by operation of the living hinge;
an actuating rod attached to the backside of the second portion by a hinged joint for actuating the movement of the second portion with respect to the first portion by a flexion of the living hinge portion; and
a supporting rod connecting the actuating rod to a point on the backside of the second portion between the hinged joint and the living hinge portion;
wherein the supporting rod acts as a brace against the second portion from being forced backward by an impact force applied from the front side somewhere between the hinged joint and the first portion.
